(19) United States
(12) Patent Application Publication
(10) Pub. No.: US 2026/0074678 A1
(43) Pub. Date: Mar. 12, 2026

(54) CIRCUIT CAPABLE OF AUTOMATICALLY ADJUSTING IMPEDANCE THEREOF

(71) Applicant: UNIVERSITY OF SEOUL INDUSTRY COOPERATION FOUNDATION, Seoul (KR)

(72) Inventors: Ju-Seung LEE, Seoul (KR); Hyeong-Min KO, Seoul (KR); Jae-Hun OH, Seoul (KR); Min-Geun JIN, Seoul (KR); Yongsam MOON, Gwacheon-si (KR)

(73) Assignee: UNIVERSITY OF SEOUL INDUSTRY COOPERATION FOUNDATION, Seoul (KR)

(21) Appl. No.: 19/064,134

(22) Filed: Feb. 26, 2025

(30) Foreign Application Priority Data
Sep. 12, 2024 (KR) 10-2024-0124569

(51) Int. Cl. H03H 11/30; H03H 17/00; H03K 19/00; H03K 19/0944

(52) U.S. Cl. CPC H03H 11/30; H03H 17/0045; H03K 19/0005; H03K 19/0944

(57) ABSTRACT

The present invention provides a circuit capable of automatically adjusting impedance thereof having a wide adjustment range and high accuracy by selecting a pull-up code and a pull-down code for obtaining resistances closest to those of a first reference resistor and a second reference resistor, respectively, using a first reference P-code and a second reference P-code, and a first reference N-code and a second reference N-code.

### CROSS-REFERENCE TO RELATED PATENT APPLICATION

This non-provisional U.S. patent application claims priority under 35 U.S.C. § 119 of Korean Patent Application No. 10-2024-0124569 filed on Sep. 12, 2024, in the KIPO, the entire contents of which are hereby incorporated by reference.

### BACKGROUND OF THE INVENTION

### 1. Field

The present invention relates to a circuit capable of automatically adjusting impedance thereof, and more particularly, to a circuit capable of automatically adjusting impedance thereof having a wide adjustment range and high accuracy. The present invention was derived as a result of research sponsored by Ministry of Trade, Industry and Energy, titled “Development of Multiprotocol-Multilink High Speed Interface PHY Supporting Multiple Bandwidth” (Project No. 2024052420).

### 2. Description of the Related Art

Generally, a transmitter and a receiver are equipped with a termination resistor having a constant resistance (e.g., 50Ω) to minimize signal reflection and increase the efficiency of signal transmission.

There are two types of termination methods: off-chip termination and on-chip termination. The off-chip termination is a method wherein a termination resistor of, for example, 50Ω is connected to a chip from the outside of the chip. The off-chip termination is advantageous in that termination resistance can be adjusted relatively accurately. However, there are three problems of the off-chip termination. First, the parasitic component of the packaging used for connecting the external termination resistor acts as a stub and generates an undesirable reflection signal, thereby causing a problem of signal distortion. Second, the disadvantage of the external termination resistor is that the transmission of a differential signal requires two external resistor elements. Third, in the case of a voltage-mode driver, it is difficult to make a termination resistor with an external resistor. This is because the driver transistor is included when making 50Ω resistor. Due to such problems described above, the general trend is to use the on-chip termination, where a termination resistor is provided inside the chip. However, since the resistor value of the on-chip termination resistor changes depending on the PVT (process, voltage, temperature) conditions, a resistance adjusting circuit is essential to adjust the termination resistance to 50Ω.

FIGS. 1A and 1B are circuit diagrams illustrating a conventional analog PMOS resistance adjusting circuit and a conventional analog NMOS resistance adjusting circuit, respectively.

Referring to FIG. 1A, the resistance of the PMOS transistor MP₁ is adjusted by an analog voltage V_{COMP1} such that the sum of the resistances of the PMOS transistors MP₁ and MP₂ and the resistance of an internal resistor R_{P} is equal to the resistance of an external reference resistor R_{EXT}.

Referring to FIG. 1B, the resistance of the NMOS transistor MN₁ is adjusted by the analog voltage V_{COMP2} such that the sum of the resistances of the NMOS transistors MN₁ and MN₂ and the resistance of an internal resistor R_{N} is equal to the resistance of an external reference resistor R_{EXT}.

The analog PMOS resistance adjusting circuit and the analog NMOS resistance adjusting circuit illustrated in FIGS. 1A and 1B, respectively, are advantageous in that accurate resistance can be obtained. However, the same is disadvantageous in that the resistance adjustment ranges thereof are small. Considering that resistance may typically vary by up to 15% due to PVT variations, the analog PMOS resistance adjusting circuit and the analog NMOS resistance adjusting circuit may not be able to sufficiently respond to the variation in resistance due to PVT variations.

FIGS. 2A and 2B are circuit diagrams illustrating a conventional digital PMOS resistance adjusting circuit and a conventional digital NMOS resistance adjusting circuit, respectively.

Referring to FIG. 2A, K count of PMOS transistors MP₁, MP₂, . . . , MP_{(K-1)} and MP_{K} connected in parallel are selectively turned on or off using a pull-up code [K-1:0] (abbreviated a “P-UP CODE” in FIGS. 2A, 3, 4 and 17) to render the sum of: the resistance MP₁∥MP₂∥ . . . ∥MP_{(K-1)}∥MP_{K} of the PMOS transistors MP₁, MP₂, . . . , MP_{(K-1)} and MP_{K} connected in parallel; the resistance of the PMOS transistor MP₀; and the resistance of the internal resistor R_{P} as close as possible to the resistance of the external reference resistor R_{EXT} (where K is a natural number).

A pull-up code generator compares the voltage across the external reference resistor R_{EXT} to 0.5×V_{DD} and generates the pull-up code [K-1:0] that renders the sum of: the resistance MP₁∥MP₂∥ . . . MP_{(K-1)}∥MP_{K} of the PMOS transistors MP₁, MP₂, . . . , MP_{(K-1)} and MP_{K} connected in parallel; the resistance of the PMOS transistor MP₀; and the resistance of the internal resistor R_{P} as close as possible to the resistance of the external reference resistor R_{EXT}.

Referring to FIG. 2B, K count of NMOS transistors MN₁, MN₂, . . . , MN_{(K-1)} and MN_{K} are selectively turned on or off using a pull-down code [K-1:0] (abbreviated a “P-DOWN CODE” in FIGS. 2B, 3, 4 and 17) to render the sum of: the resistance MN₁∥MN₂∥ . . . ∥MN_{(K-1)}∥MN_{K} of the NMOS transistors MN₁, MN₂, . . . , MN_{(K-1)} and MN_{K} connected in parallel; the resistance of the NMOS transistor MN₀; and the resistance of the internal resistor R_{N} as close as possible to the resistance of the external reference resistor R_{EXT}

The pull-down code generator compares the voltage across the external reference resistor R_{EXT} to 0.5×V_{DD} and generates the pull-down code [K-1:0] that renders the sum of: the resistance MN₁∥MN₂∥ . . . ∥MN_{(K-1)}∥MN_{K} of the NMOS transistors MN₁, MN₂, . . . , MN_{(K-1)} and MN_{K} connected in parallel; the resistance of the NMOS transistor MN₀; and the resistance of the internal resistor R_{N} as close as possible to the resistance of the external reference resistor R_{EXT}.

The pull-up code [K-1:0] and the pull-down code [K-1:0] determined through the above-described process are applied to the voltage-mode driver illustrated in FIG. 3.

FIG. 3 is a circuit diagram illustrating a conventional voltage-mode driver.

Referring to FIG. 3, the pull-up code [K-1:0] is applied to the PMOS transistors MP_{D11}, MP_{D12}, . . . , MP_{D1(K-1)} and MP_{D1K}, and the pull-down code [K-1:0] is applied to the NMOS transistors MN_{D11}, MN_{D12}, . . . , MN_{D1(K-1)} and MN_{D1K}. Here, depending on the input IN_{P} and IN_{N}, only one of the PMOS path and the NMOS path is turned on, and when the corresponding cell is viewed from the OUT_{P} and OUT_{N}, the resistance of each cell including the resistor R_{INT} becomes as close as possible to the resistance of the target resistor R_{EXT}.

A technology for adjusting impedance using the above-described pull-up code and pull-down code is disclosed in Korean Patent No. 10-1204672.

According to Patent No. 10-1204672, when repeating between the two codes closest to 50Ω, an end signal is generated, and one of the two codes is arbitrarily selected as the pull-down code or the pull-up code. However, when one of the two codes is arbitrarily selected, there is a probability of 50% that the code that is further from 50Ω is selected as the pull-down code or the pull-up code.

### SUMMARY OF THE INVENTION

It is an object of the present invention to provide a circuit capable of automatically adjusting impedance thereof having a wide adjustment range and high accuracy.

A circuit capable of automatically adjusting impedance thereof according to a first embodiment of the present invention includes: a first voltage divider comprising: a first pull-up resistor and a second pull-up resistor connected in parallel and having resistances, respectively, varying according to a reference P-code applied thereto; and a first reference resistor having a constant resistance and connected in series with the first pull-up resistor and the second pull-up resistor connected in parallel, a pull-up code selector sequentially applying: a first reference P-code and the first reference P-code; the first reference P-code and a second reference P-code; and the second reference P-code and the second reference P-code to the first pull-up resistor and the second pull-up resistor, respectively; a first comparator providing a comparison value V_{COMP1} to the pull-up code selector wherein the comparison value V_{COMP1} is obtained by comparing 0.5×V_{DD} to a voltage VD_{IV1} across the first reference resistor when a voltage V_{DD} is applied to the first voltage divider; a second voltage divider comprising: a second reference resistor having a resistance varying according to a pull-up code applied by the pull-up code selector; and a first pull-down resistor and a second pull-down resistor connected in parallel and having resistances, respectively, varying according to a reference N-code applied thereto wherein the first pull-down resistor and the second pull-down resistor are connected in series with the second reference resistor; a pull-down code selector sequentially applying: a first reference N-code and the first reference N-code; the first reference N-code and a second reference N-code; and the second reference N-code and the second reference N-code to the first pull-down resistor and the second pull-down resistor, respectively; and a second comparator providing a comparison value V_{COMP2} to the pull-down code selector wherein the comparison value V_{COMP2} is obtained by comparing 0.5×V_{DD} to a voltage V_{DIV2} across the first pull-down resistor and the second pull-down resistor when the voltage V_{DD} is applied to the second voltage divider, wherein the first comparator performs a comparison each time the reference P-code is applied and provides three comparison values V_{COMP1} to the pull-up code selector, the pull-up code selector selects one of the first reference P-code and the second reference P-code as a pull-up code based on the three comparison values V_{COMP1}, the pull-up code minimizing a difference between: a resistance of the first reference resistor; and a resistance of the first pull-up resistor and the second pull-up resistor connected in parallel, the second comparator performs a comparison each time the reference N-code is applied and provides three comparison values V_{COMP2} to the pull-down code selector, and the pull-down code selector selects one of the first reference N-code and the second reference N-code as a pull-down code based on the three comparison values V_{COMP2}, the pull-down code minimizing the difference between: a resistance of the second reference resistor; and a resistance of the first pull-down resistor and the second pull-down resistor connected in parallel (where [second reference P-code] is equal to [first reference P-code+1], and [second reference N-code] is equal to [first reference N-code+1]).

The reference P-code includes binary data of K bits, and each of the first pull-up resistor and the second pull-up resistor includes K counts of PMOS transistors provided with gates having the binary data of K bits applied thereto, respectively (where K is a natural number).

The three comparison values V_{COMP1} include a first comparison value, a second comparison value and a third comparison value, and the pull-up code selector selects the first reference P-code as the pull-up code when the first comparison value=1, the second comparison value=0 and the third comparison value=0 are satisfied, and selects the second reference P-code as the pull-up code when the first comparison value=1, the second comparison value=1 and the third comparison value=0 are satisfied.

The pull-up code selector: (i) increases each of the first reference P-code and the second reference P-code by 1 and then sequentially applies increased first reference P-code and increased second reference P-code to the first pull-up resistor and the second pull-up resistor when the first comparison value=1, the second comparison value=1, and the third comparison value=1 are satisfied; and (ii) selects one of the increased first reference P-code and the increased second reference P-code as the pull-up code based on comparison values of the first comparator obtained from the increased first reference P-code and the increased second reference P-code, the pull-up code minimizing the difference between: the resistance of the first reference resistor; and the resistance of the first pull-up resistor and the second pull-up resistor connected in parallel.

The pull-up code selector: (i) decreases each of the first reference P-code and the second reference P-code by 1 and then sequentially applies decreased first reference P-code and decreased second reference P-code to the first pull-up resistor and the second pull-up resistor when the first comparison value=0, the second comparison value=0, and the third comparison value=0 are satisfied; and (ii) selects one of the decreased first reference P-code and the decreased second reference P-code as the pull-up code based on comparison values of the first comparator obtained from the decreased first reference P-code and the decreased second reference P-code, the pull-up code minimizing the difference between: the resistance of the first reference resistor; and the resistance of the first pull-up resistor and the second pull-up resistor connected in parallel.

The reference N-code includes binary data of K bits, and each of the first pull-down resistor and the second pull-down resistor includes K counts of NMOS transistors provided with gates having the binary data of K bits applied thereto, respectively (where K is a natural number).

The three comparison values V_{COMP2} include a first comparison value, a second comparison value and a third comparison value, and the pull-down code selector selects the first reference N-code as the pull-down code when the first comparison value=1, the second comparison value=0 and the third comparison value=0 are satisfied, and selects the second reference N-code as the pull-down code when the first comparison value=1, the second comparison value=1 and the third comparison value=0 are satisfied.

The pull-down code selector: (i) increases each of the first reference N-code and the second reference N-code by 1 and then sequentially applies increased first reference N-code and increased second reference N-code to the first pull-down resistor and the second pull-down resistor when the first comparison value=1, the second comparison value=1, and the third comparison value=1 are satisfied; and (ii) selects one of the increased first reference N-code and the increased second reference N-code as the pull-down code based on comparison values of the second comparator obtained from the increased first reference N-code and the increased second reference N-code, the pull-down code minimizing the difference between: the resistance of the second reference resistor; and the resistance of the first pull-down resistor and the second pull-down resistor connected in parallel.

The pull-down code selector: (i) decreases each of the first reference N-code and the second reference N-code by 1 and then sequentially applies decreased first reference N-code and decreased second reference N-code to the first pull-down resistor and the second pull-down resistor when the first comparison value=0, the second comparison value=0, and the third comparison value=0 are satisfied; and (ii) selects one of the decreased first reference N-code and the decreased second reference N-code as the pull-down code based on comparison values of the second comparator obtained from the decreased first reference N-code and the decreased second reference N-code, the pull-down code minimizing the difference between: the resistance of the first reference resistor; and the resistance of the first pull-down resistor and the second pull-down resistor connected in parallel.

A circuit capable of automatically adjusting impedance thereof according to a second embodiment of the present invention includes: a first voltage divider including: a first pull-down resistor and a second pull-down resistor connected in parallel and having resistances, respectively, varying according to a reference N-code applied thereto; and a first reference resistor having a constant resistance and connected in series with the first pull-down resistor and the second pull-down resistor connected in parallel, a pull-down code selector sequentially applying: a first reference N-code and the first reference N-code; the first reference N-code and a second reference N-code; and the second reference N-code and the second reference N-code to the first pull-down resistor and the second pull-down resistor, respectively; a first comparator providing a comparison value V_{COMP1} to the pull-down code selector wherein the comparison value V_{COMP1} is obtained by comparing 0.5×V_{DD} to a voltage V_{DIV1} across the first pull-down resistor and the second pull-down resistor connected in parallel when a voltage V_{DD} is applied to the first voltage divider; a second voltage divider including: a second reference resistor having a resistance varying according to a pull-down code applied by the pull-down code selector; and a first pull-up resistor and a second pull-up resistor connected in parallel and having resistances, respectively, varying according to a reference P-code applied thereto wherein the first pull-up resistor and the second pull-up resistor are connected in series with the second reference resistor; a pull-up code selector sequentially applying: a first reference P-code and the first reference P-code; the first reference P-code and a second reference P-code; and the second reference P-code and the second reference P-code to the first pull-up resistor and the second pull-up resistor, respectively; and a second comparator providing a comparison value V_{COMP2} to the pull-up code selector wherein the comparison value V_{COMP2} is obtained by comparing 0.5×V_{DD} to a voltage V_{DIV2} across the second reference resistor when the voltage V_{DD} is applied to the second voltage divider, wherein the first comparator performs a comparison each time the reference N-code is applied and provides three comparison values V_{COMP1} to the pull-down code selector, the pull-down code selector selects one of the first reference N-code and the second reference N-code as a pull-down code based on the three comparison values V_{COMP1}, the pull-down code minimizing a difference between: a resistance of the first reference resistor; and a resistance of the first pull-down resistor and the second pull-down resistor connected in parallel, the second comparator performs a comparison each time the reference P-code is applied and provides three comparison values V_{COMP2} to the pull-up code selector, and the pull-up code selector selects one of the first reference P-code and the second reference P-code as a pull-up code based on the three comparison values V_{COMP2}, the pull-up code minimizing the difference between: a resistance of the second reference resistor; and a resistance of the first pull-up resistor and the second pull-up resistor connected in parallel (where [second reference N-code] is equal to [first reference N-code+1], and [second reference P-code] is equal to [first reference P-code+1]).

### BRIEF DESCRIPTION OF DRAWINGS

FIGS. 1A and 1B are circuit diagrams illustrating a conventional analog PMOS resistance adjusting circuit and a conventional analog NMOS resistance adjusting circuit, respectively.

FIGS. 2A and 2B are circuit diagrams illustrating a conventional digital PMOS resistance adjusting circuit and a conventional digital NMOS resistance adjusting circuit, respectively.

FIG. 3 is a circuit diagram illustrating a conventional voltage-mode driver.

FIG. 4 is a circuit diagram illustrating a circuit capable of automatically adjusting impedance thereof according to a first embodiment of the present invention.

FIG. 5 is a circuit diagram illustrating a first pull-up resistor (or second pull-up resistor) according to the present invention.

FIG. 6 is a circuit diagram illustrating a second reference resistor according to the present invention.

FIG. 7 is a circuit diagram illustrating a first pull-down resistor (or second pull-down resistor) according to the present invention.

FIGS. 8A to 8C are circuit diagrams illustrating a first pull-up resistor and a second pull-up resistor, respectively, when reference P-codes X₁ and X₁+1 are applied according to the present invention.

FIG. 9 is a graph illustrating resistances when the reference P-codes X₁ and X₁+1 are applied according to the present invention.

FIGS. 10A to 10C are circuit diagrams illustrating a first pull-up resistor and a second pull-up resistor, respectively, when reference P-codes X₂ and X₂+1 are applied according to the present invention.

FIG. 11 is a graph illustrating resistances when the reference P-codes X₂ and X₂+1 are applied according to the present invention.

FIG. 12 is a circuit diagram illustrating a second reference resistor with a pull-up code applied thereto according to the present invention.

FIG. 13A to 13C are circuit diagrams illustrating a first pull-down resistor and a second pull-down resistor, respectively, when reference N-codes Y₁ and Y₁+1 are applied according to the present invention.

FIG. 14 is a graph illustrating resistances when the reference N-codes Y₁ and Y₁+1 are applied according to the present invention.

FIG. 15A to 15C are circuit diagrams illustrating a first pull-down resistor and a second pull-down resistor, respectively, when reference N-codes Y₂ and Y₂+1 are applied according to the present invention.

FIG. 16 is a graph illustrating resistances when the reference N-code Y₂ and Y₂+1 are applied according to the present invention.

FIG. 17 is a circuit diagram illustrating a circuit capable of automatically adjusting impedance thereof according to a second embodiment of the present invention.

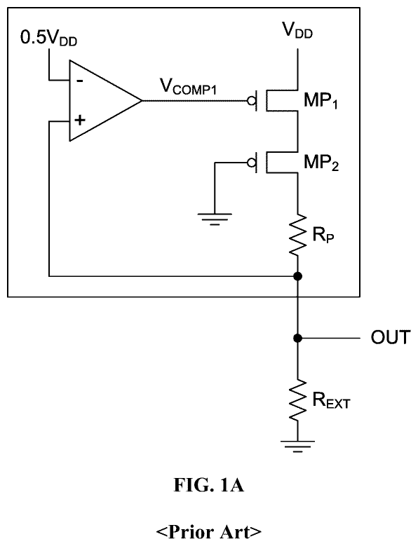

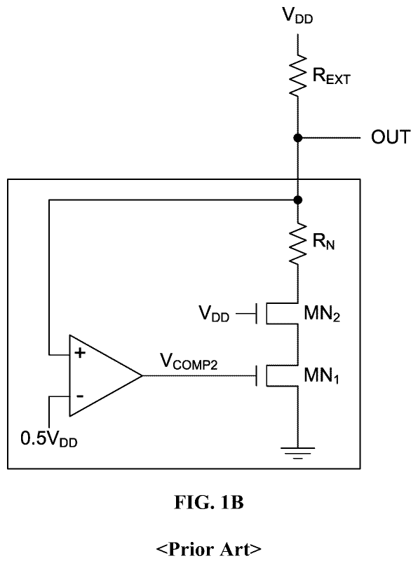

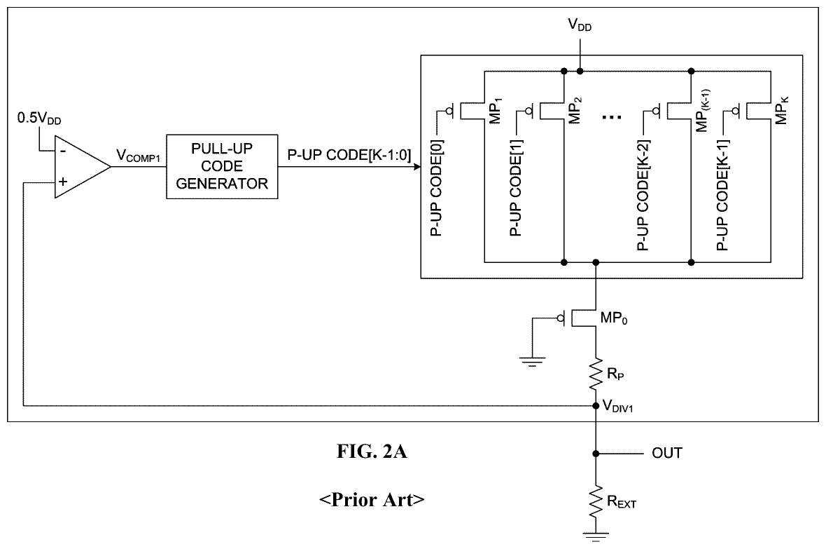

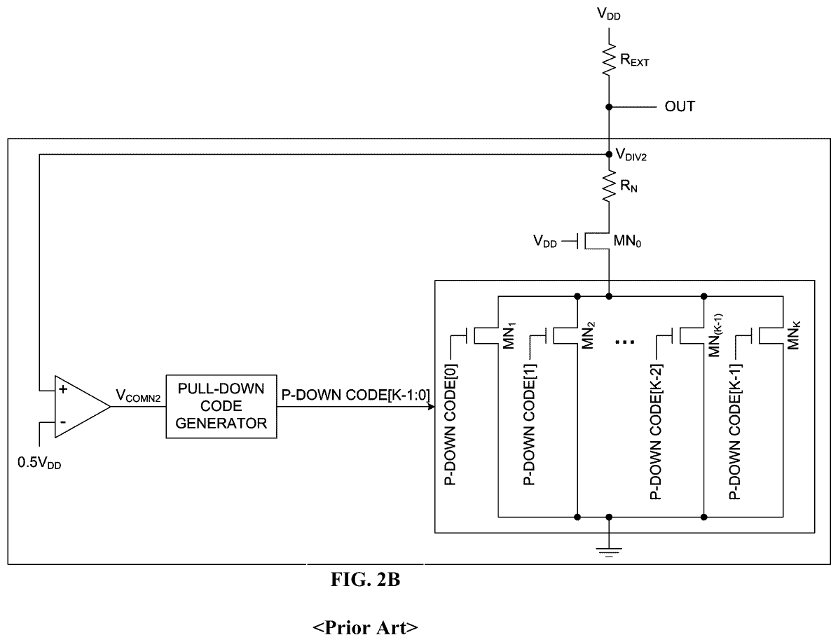

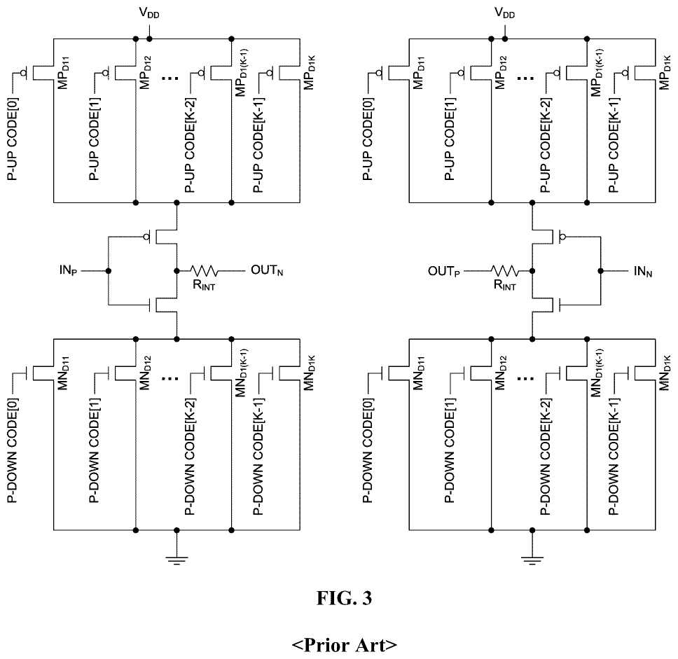

### DETAILED DESCRIPTION OF THE INVENTION

Hereinafter, a circuit capable of automatically adjusting impedance thereof according to the present invention will be described in detail with reference to the accompanying drawings.

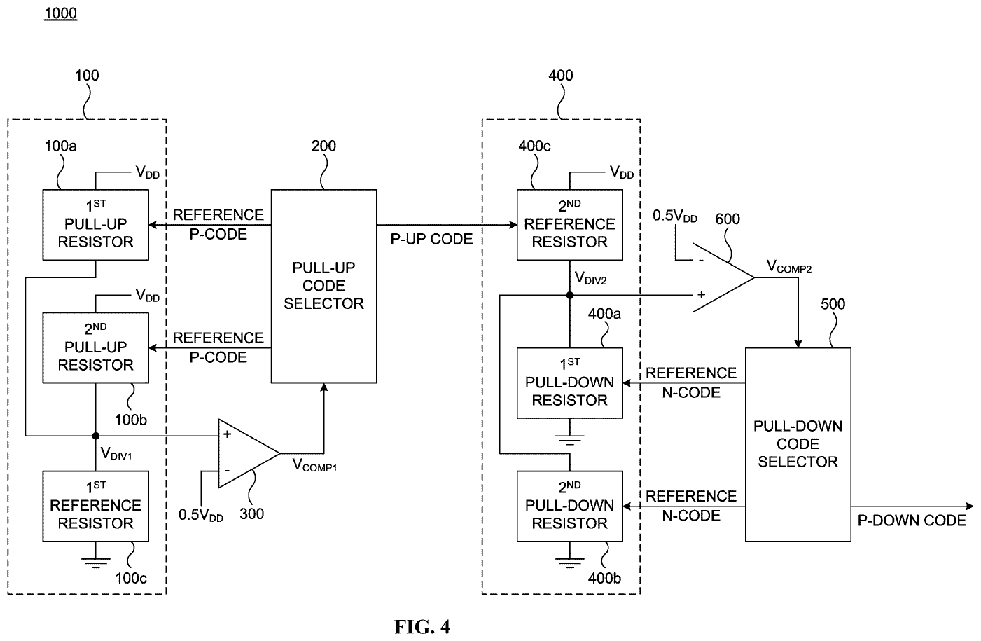

FIG. 4 is a circuit diagram illustrating a circuit capable of automatically adjusting impedance thereof according to a first embodiment of the present invention.

Referring to FIG. 4, a circuit 1000 capable of automatically adjusting impedance thereof according to the first embodiment of the present invention includes: a first voltage divider 100; a pull-up code selector 200; a first comparator 300; a second voltage divider 400; a pull-down code selector 500; and a second comparator 600.

The first voltage divider 100 includes: a first pull-up resistor 100a; a second pull-up resistor 100b; and a first reference resistor 100c.

The resistance of the first pull-up resistor 100a changes according to a reference P-code [K-1:0] of K bits applied thereto (where K is a natural number).

The resistance of the second pull-up resistor 100b connected in parallel with the first pull-up resistor 100a changes according to the reference P-code [K-1:0] of K bits applied thereto. The configuration of the second pull-up resistor 100b is substantially the same as that of the first pull-up resistor 100a.

The first reference resistor 100c has a constant resistance (e.g., 50Ω) and is connected in series with the first pull-up resistor 100a and the second pull-up resistor 100b connected in parallel.

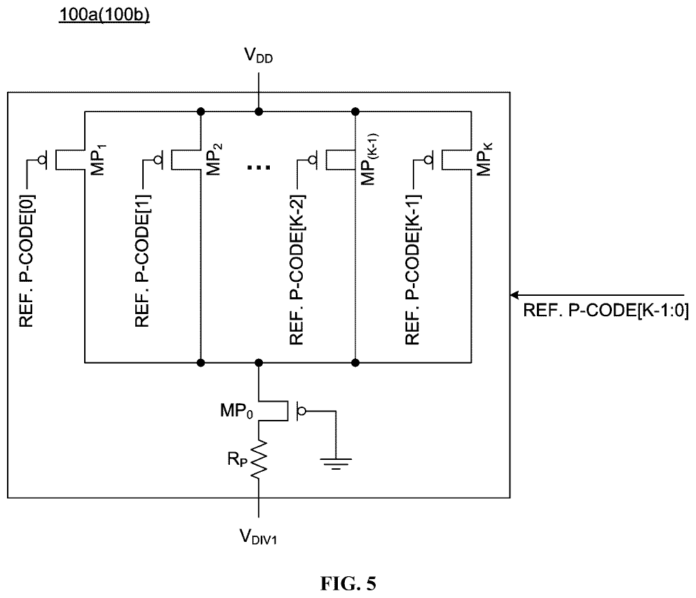

The configuration of the first pull-up resistor 100a (or the second pull-up resistor 100b) will be described in detail with reference to FIG. 5.

FIG. 5 is a circuit diagram illustrating the first pull-up resistor 100a (or the second pull-up resistor 100b) according to the present invention.

Referring to FIG. 5, the first pull-up resistor 100a includes: K count of PMOS transistors MP₁ to MP_{K} connected in parallel; a PMOS transistor MP₀; and a resistor R_{P}.

The K count of PMOS transistors MP₁ to MP_{K} are turned on or turned off according to the reference P-code [K-1:0] (abbreviated as “REF. P-CODE” in FIGS. 5, 9 and 11) applied thereto. That is, the resistance of the first pull-up resistor 100a changes depending on the sum of the channel width (or area) that varies according to the number of PMOS transistors turned on (or turned off) among the K count of PMOS transistors MP₁ to MP_{K}.

For example, when “0111”, which is a 4-bit reference P-code [3:0], is applied, “H” (i.e., reference P-code [0]), “H” (i.e., reference P-code [1]), “H” (i.e., reference P-code [2]), and “L” (i.e., reference P-code [3]) are applied to the PMOS transistors MP₁ to MP₄, respectively. As a result, the PMOS transistors MP₁ to MP₄ are turned off, turned off, turned off, and turned on, respectively.

The resistance of the first pull-up resistor 100a is (MP₁∥MP₂∥ . . . ∥MP_{(K-1)}∥MP_{K})+MP₀+RP. Therefore, it should be understood that the resistance of the first pull-up=resistor 100a changes based on the sum of the channel width (or area) that varies according to the number of the PMOS transistors MP₁ to MP_{K} that are turned on (or turned off).

Since the configuration of the second pull-up resistor 100b is the same as that of the first pull-up resistor 100a, the resistance of the second pull-up resistor 100b changes depending on the sum of the channel width (or area) that varies according to the number of the PMOS transistors MP₁ to MP_{K} that are turned on (or turned off).

It is preferable that the median of the range of the resistance of the first pull-up resistor 100a be approximately twice the resistance of the first reference resistor 100c. That is, the resistance of the first pull-up resistor 100a varies around twice the resistance of the first reference resistor 100c. The same applies to the second pull-up resistor 100b. Therefore, when the first pull-up resistor 100a and the second pull-up resistor 100b are connected in parallel, their resistance varies around the resistance of the first reference resistor 100c.

In addition, the resistance of each transistor may be adjusted by properly designing the size of the channel width (or area) of the transistors constituting the first pull-up resistor 100a and the second pull-up resistor 100b, and accordingly, the resistances of the first pull-up resistor 100a and the second pull-up resistor 100b are adjusted. For example, the resistances of the first pull-up resistor 100a and the second pull-up resistor 100b may be designed to increase as the value of the applied reference P-code increases.

Referring back to FIG. 4, a voltage V_{DD} is applied to the first voltage divider 100, and the applied voltage V_{DD} is divided according to the resistances of the first pull-up resistor 100a, the second pull-up resistor 100b, and the first reference resistor 100c.

For example, when the resistances of the first pull-up resistor 100a, the second pull-up resistor 100b, and the first reference resistor 100c are R_{P1}, R_{P2}, and R_{REF1}, respectively, the voltage V_{DIV1} across the first reference resistor 100c is as shown in Equation 1 below.

$${V}_{DIV 1} = \frac{{R}_{REF 1}}{( {R}_{P 1} ‖ {R}_{P 2} ) + {R}_{REF 1}} \times {V}_{DD} \qquad [ Equation 1 ]$$

That is, the voltage V_{DIV1} varies depending on the resistance R_{P1}∥R_{P2} which is the resistance of the first pull-up resistor 100a and the second pull-up resistor 100b connected in parallel. Here, since each of R_{P1} and R_{P2} vary around 2×R_{REF1}, R_{P1}∥R_{P2} varies around R_{REF1}.

Still referring to FIG. 4, the pull-up code selector 200 applies the reference P-code [K-1:0] to the first pull-up resistor 100a and the second pull-up resistor 100b, respectively.

The reference P-code [K-1:0] may include a first reference P-code [K-1:0] and a second reference P-code [K-1:0]. Here, the first reference P-code [K-1:0] and the second reference P-code [K-1:0] satisfy the relationship: second reference P-code [K-1:0]=first reference P-code [K-1:0]+1. That is, the second reference P-code [K-1:0] is binary data of K bits that is greater than the first reference P-code [K-1:0] by 1.

For example, when 4-bit first reference P-code [3:0] is “1000”, a second reference P-code [3:0] is “1001”.

The pull-up code selector 200 sequentially applies: the first reference P-code [K-1:0] and the first reference P-code [K-1:0] to the first pull-up resistor 100a and the second pull-up resistor 100b, respectively; the first reference P-code [K-1:0] and the second reference P-code [K-1:0] to the first pull-up resistor 100a and the second pull-up resistor 100b, respectively; and the second reference P-code [K-1:0] and the second reference P-code [K-1:0] to the first pull-up resistor 100a and the second pull-up resistor 100b, respectively.

For example, the pull-up code selector 200 may apply: “1000” and “1000” to the first pull-up resistor 100a and the second pull-up resistor 100b, respectively, “1000” and “1001” to the first pull-up resistor 100a and the second pull-up resistor 100b, respectively, and “1001” and “1001” to the first pull-up resistor 100a and the second pull-up resistor 100b, respectively. However, the order of application may be changed.

The resistances of the first pull-up resistor 100a and the second pull-up resistor 100b varies depending on the first reference P-code [K-1:0] and second reference P-code [K-1:0] applied thereto. Therefore, when “1000” and “1000”, “1000” and “1001”, “1001” and “1001” are applied for example, three different resistances are generated, resulting in three different voltages V_{DIV1}.

The first comparator 300 compares the voltage V_{DIV1} to 0.5×V_{DD} and provides the resulting comparison value V_{COMP1} to the pull-up code selector 200.

Specifically, as described above, since three different voltages V_{DIV1} are generated when the first reference P-code [K-1:0] and the second reference P-code [K-1:0] are applied to the first pull-up resistor 100a and the second pull-up resistor 100b, the first comparator 300 compares each of the three voltages V_{DIV1} to 0.5×V_{DD} and provides the three comparison values V_{COMP1} to the pull-up code selector 200.

For example, the first comparator 300 outputs V_{COMP1}=1 when V_{DIV1}>0.5×V_{DD}, and outputs V_{COMP1}=0 when VDIV1≤0.5×V_{DD}.

The pull-up code selector 200 selects, based on three comparison values V_{COMP1}, one of the first reference P-code [K-1:0] and the second reference P-code [K-1:0] as a pull-up code [K-1:0] which minimizes the difference between R_{P1}∥R_{P2} and R_{REF1}. This process will be described later.

The second voltage divider 400 includes: a first pull-down resistor 400a; a second pull-down resistor 400b; and a second reference resistor 400c.

The resistance of the second reference resistor 400c changes according to the pull-up code [K-1:0] applied by the pull-up code selector 200. The second reference resistor 400c is connected in series with the first pull-down resistor 400a and the second pull-down resistor 400b, which are connected in parallel.

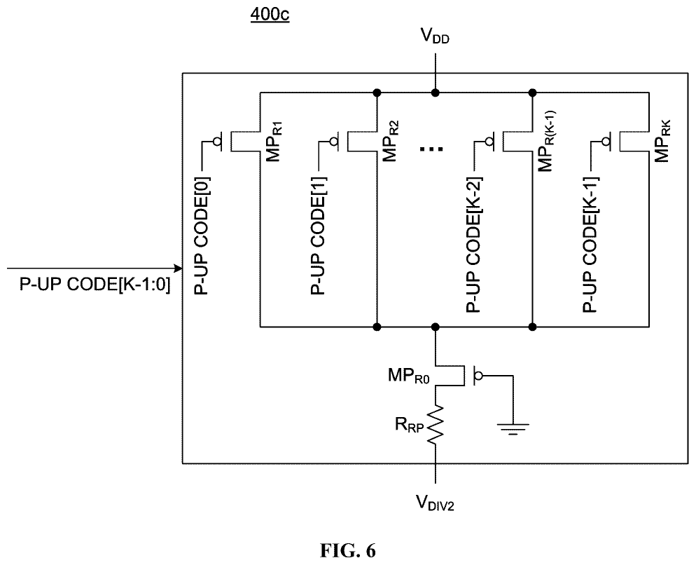

The configuration of the second reference resistor 400c is described in detail with reference to FIG. 6.

FIG. 6 is a circuit diagram illustrating the second reference resistor 400c according to the present invention.

Referring to FIG. 6, the second reference resistor 400c according to the present invention includes: K count of PMOS transistors MP_{R1} to MP_{RK} connected in parallel; a PMOS transistor MP_{R0}; and a resistor R_{RP}.

The configuration of the second reference resistor 400c is substantially the same as that of the first pull-up resistor 100a (or the second pull-up resistor 100b) described above. That is, the K count of PMOS transistors MP_{R1} to MP_{RK} are turned on or off according to the pull-up code [K-1:0] applied thereto, and thus the resistance thereof varies. However, the resistance of the second reference resistor 400c varies around the resistance of the first reference resistor 100c.

The resistance of the first pull-down resistor 400a changes according to the reference N-code [K-1:0] of K bits applied thereto.

The resistance of the second pull-down resistor 400b connected in parallel with the first pull-down resistor 400a changes according to the reference N-code [K-1:0] of K bits. The configuration of the second pull-down resistor 400b is substantially the same as that of the first pull-down resistor 400a.

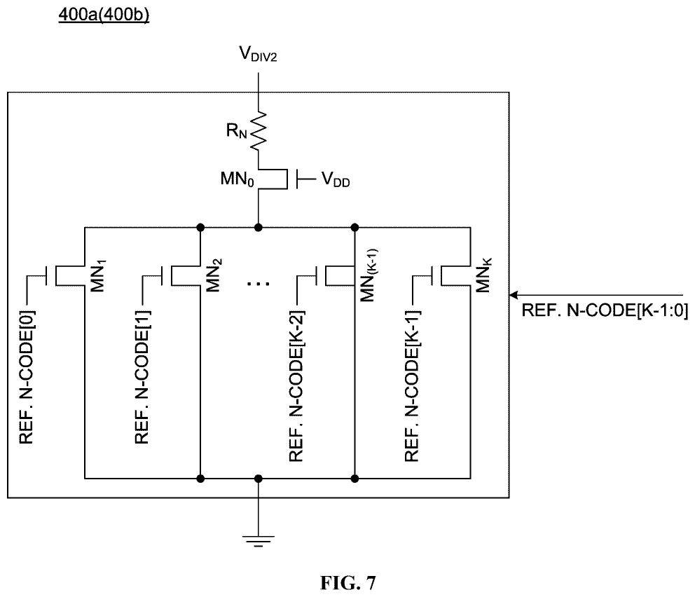

FIG. 7 is a circuit diagram illustrating the first pull-down resistor 400a (or the second pull-down resistor 400b) according to the present invention.

Referring to FIG. 7, the first pull-down resistor 400a includes: K count of NMOS transistors MN₁ to MN_{K} connected in parallel, an NMOS transistor MN₀, and a resistor R_{N}.

The K count of NMOS transistors MN₁ to MN_{K} are turned on or turned off according to the reference N-code [K-1:0] (abbreviated as “REF. N-CODE” in FIGS. 7, 14 and 16) applied thereto. That is, the resistance of the first pull-down resistor 400a changes depending on the sum of the channel width (or area) that varies according to the number of NMOS transistors turned on (or turned off) among the K count of NMOS transistors MN₁ to MN_{K}.

For example, when “0111”, which is a 4-bit reference N-code [3:0], is applied, “H” (i.e., reference N-code [0]), “H” (i.e., reference N-code [1]), “H” (i.e., reference N-code [2]), and “L” (i.e., reference N-code [3]) are applied to the NMOS transistors MN₁ to MN₄, respectively. As a result, the NMOS transistors MN₁ to MN₄ are turned on, turned on, turned on, and turned off, respectively.

The resistance of the first pull-down resistor 400a is (MN₁∥MN₂∥ . . . ∥MN_{(K-1)}∥MN_{K})+MN₀+R_{N}. Therefore, it should be understood that the resistance of the first pull-down resistor 400a changes based on the sum of the channel width (or area) that varies according to the number of the NMOS transistors MN₁ to MN_{K} that are turned on (or turned off).

Since the configuration of the second pull-down resistor 400b is the same as that of the first pull-down resistor 400a, the resistance of the second pull-down resistor 400b changes depending on the sum of the channel width (or area) that varies according to the number of the NMOS transistors MN₁ to MN_{K} that are turned on (or turned off).

It is preferable that the median of the range of the resistance of the first pull-down resistor 400a be approximately twice the resistance of the second reference resistor 400c. That is, the resistance of the first pull-down resistor 400a varies around twice the resistance of the second reference resistor 400c. The same applies to the second pull-down resistor 400b. Therefore, when the first pull-down resistor 400a and the second pull-down resistor 400b are connected in parallel, their resistance varies around the resistance of the second reference resistor 400c.

In addition, the resistance of each transistor may be adjusted by properly designing the size of the channel width (or area) of the transistors constituting the first pull-down resistor 400a and the second pull-down resistor 400b, and accordingly, the resistances of the first pull-down resistor 400a and the second pull-down resistor 400b are adjusted. For example, the resistances of the first pull-down resistor 400a and the second pull-down resistor 400b may be designed to decrease as the value of the applied reference N-code increases.

Referring back to FIG. 4, a voltage V_{DD} is applied to the second voltage divider 400, and the applied voltage V_{DD} is divided according to the resistances of the second reference resistor 400c, the first pull-down resistor 400a, and the second pull-down resistor 400b.

For example, when the resistances of the second reference resistor 400c, the first pull-down resistor 400a, and the second pull-down resistor 400b are R_{REF2}, R_{N1}, and R_{N2}, respectively, the voltage V_{DIV2} across the first pull-down resistor 400a and the second pull-down resistor 400b connected in parallel is as shown in Equation 2 below.

$${V}_{DIV 2} = \frac{( {R}_{N 1} ‖ {R}_{N 2} )}{( {R}_{N 1} ‖ {R}_{N 2} ) + {R}_{REF 2}} \times {V}_{DD} \qquad [ Equation 2 ]$$

That is, the voltage V_{DIV2} varies depending on the resistance R_{N1}∥R_{N2} which is the resistance of the first pull-down resistor 400a and the second pull-down resistor 400b connected in parallel. Here, since each of R_{N1} and R_{N2} vary around 2×R_{REF2}, R_{N1}∥R_{N2} varies around R_{REF2}.

Still referring to FIG. 4, the pull-down code selector 500 applies the reference N-code [K-1:0] to the first pull-down resistor 400a and the second pull-down resistor 400b, respectively.

The reference N-code [K-1:0] may include a first reference N-code [K-1:0] and a second reference N-code [K-1:0]. Here, the first reference N-code [K-1:0] and the second reference N-code [K-1:0] satisfy the relationship: second reference N-code [K-1:0]=first reference N-code [K-1:0]+1. That is, the second reference N-code [K-1:0] is binary data of K bits that is greater than the first reference N-code [K-1:0] by 1.

For example, when 4-bit first reference N-code [3:0] is “0111”, a second reference N-code [3:0] is “1000”.

The pull-down code selector 500 sequentially applies: the first reference N-code [K-1:0] and the first reference N-code [K-1:0] to the first pull-down resistor 400a and the second pull-down resistor 400b, respectively; the first reference N-code [K-1:0] and the second reference N-code [K-1:0] to the first pull-down resistor 400a and the second pull-down resistor 400b, respectively; and the second reference N-code [K-1:0] and the second reference N-code [K-1:0] to the first pull-down resistor 400a and the second pull-down resistor 400b, respectively.

For example, the pull-down code selector 500 may apply: “0111” and “0111” to the first pull-down resistor 400a and the second pull-down resistor 400b, respectively, “0111” and “1000” to the first pull-down resistor 400a and the second pull-down resistor 400b, respectively, and “1000” and “1000” to the first pull-down resistor 400a and the second pull-down resistor 400b, respectively. However, the order of application may be changed.

The resistances of the first pull-down resistor 400a and the second pull-down resistor 400b varies depending on the first reference N-code [K-1:0] and second reference N-code [K-1:0] applied thereto. Therefore, when “0111” and “0111”, “0111” and “1000”, “1000” and “1000” are applied for example, three different resistances are generated, resulting in three different voltages V_{DIV2}.

The second comparator 600 compares the voltage V_{DIV2} to 0.5×V_{DD} and provides the resulting comparison value V_{COMP2} to the pull-down code selector 500.

Specifically, as described above, since three different voltages V_{DIV2} are generated when the first reference N-code [K-1:0] and the second reference N-code [K-1:0] are applied to the first pull-down resistor 400a and the second pull-down resistor 400b, the second comparator 600 compares each of the three voltages V_{DIV2} to 0.5×V_{DD} and provides the three comparison values V_{COMP2} to the pull-down code selector 500.

For example, the second comparator 600 outputs V_{COMP2}=1 when V_{DIV2}>0.5×V_{DD}, and outputs V_{COMP2}=0 when V_{DIV2}≤0.5×V_{DD}.

The pull-down code selector 500 selects, based on three comparison values V_{COMP2}, one of the first reference N-code [K-1:0] and the second reference N-code [K-1:0] as a pull-down code [K-1:0] which minimizes the difference between R_{N1}∥R_{N2} and R_{REF2}. This process will be described later.

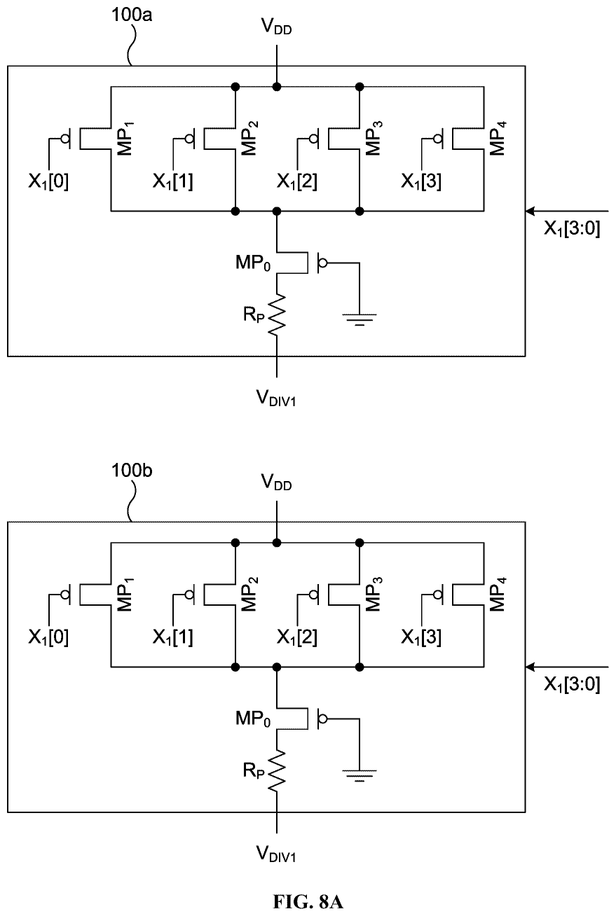

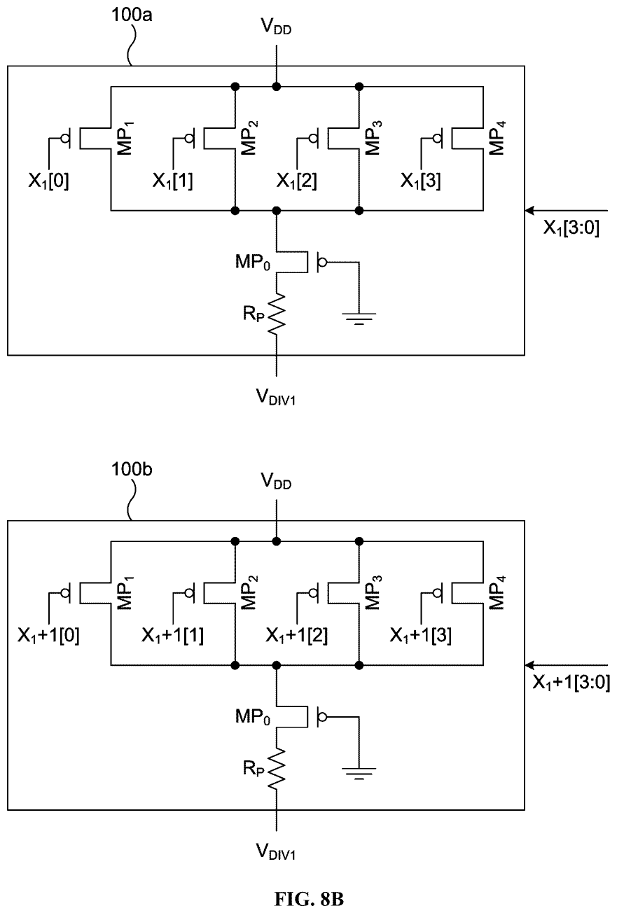

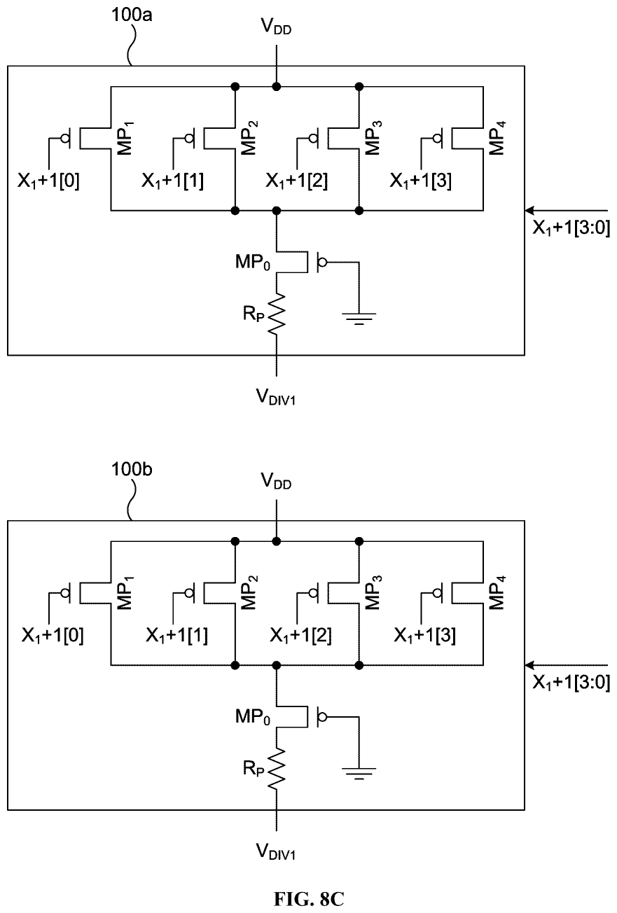

Hereinafter, the operation of the circuit capable of automatically adjusting impedance thereof according to the present invention will be described in detail with reference to FIGS. 8A to 16.

First, in order to describe the pull-up code selection process of the pull-up code selector 200, it is assumed that K=4, the resistance R_{REF1} of the first reference resistor 100c is 50Ω, the resistance R_{P1} of the first pull-up resistor 100a and the resistance R_{P2} of the second pull-up resistor 100b are both 94Ω when the first reference P-code [3:0] (=X₁) is applied thereto, and the resistance R_{P1} of the first pull-up resistor 100a and the resistance R_{P2} of the second pull-up resistor 100b are both 102Ω when the second reference P-code [3:0] (=X₁+1) is applied.

FIGS. 8A to 8C are circuit diagrams illustrating the first pull-up resistor 100a and the second pull-up resistor 100b, respectively, when the first reference P-code [3:0] (=X₁) and the second reference P-code [3:0] (=X₁+1) are applied according to the present invention.

First, referring to FIG. 8A, the first reference P-code [3:0] (=X₁) is applied to each of the first pull-up resistor 100a and the second pull-up resistor 100b.

When X₁ is applied to each of the first pull-up resistor 100a and the second pull-up resistor 100b, the resistance R_{P1} of the first pull-up resistor 100a and the resistance R_{P2} of the second pull-up resistor 100b are both 94Ω. Thus, R_{P1}∥R_{P2}=47Ω.

Here, the voltage V_{DIV11} across the first reference resistor 100c may be calculated from Equation 1 as shown in Equation 3 below.

$${V}_{DIV 11} = \frac{{R}_{REF 1}}{( {R}_{P 1} ‖ {R}_{P 2} ) + {R}_{REF 1}} \times {V}_{DD} = \frac{50}{47 + 50} \times {V}_{DD} \approx 0.515 {V}_{DD} \qquad [ Equation 3 ]$$

Next, referring to FIG. 8B, the first reference P-code [3:0] (=X₁) and the second reference P-code [3:0] (=X₁+1) are applied to the first pull-up resistor 100a and the second pull-up resistor 100b, respectively.

When X₁ and X₁+1 are applied to the first pull-up resistor 100a and the second pull-up resistor 100b, respectively, the resistance R_{P1} of the first pull-up resistor 100a and the resistance R_{P2} of the second pull-up resistor 100b are 94Ω and 102Ω, respectively. Thus, R_{P1}∥R_{P2}≈49Ω.

Here, the voltage V_{DIV12} across the first reference resistor 100c may be calculated from Equation 1 as shown in Equation 4 below.

$${V}_{DIV 12} = \frac{{R}_{REF 1}}{( {R}_{P 1} ‖ {R}_{P 2} ) + {R}_{REF 1}} \times {V}_{DD} = \frac{50}{49 + 50} \times {V}_{DD} \approx 0.505 {V}_{DD} \qquad [ Equation 4 ]$$

Next, referring to FIG. 8C, the second reference P-code [3:0] (=X₁+1) is applied to each of the first pull-up resistor 100a and the second pull-up resistor 100b.

When X₁+1 is applied to each of the first pull-up resistor 100a and the second pull-up resistor 100b, the resistance R_{P1} of the first pull-up resistor 100a and the resistance R_{P2} of the second pull-up resistor 100b are both 102Ω. Thus, R_{P1}∥R_{P2}=51Ω.

Here, the voltage V_{DIV13} across the first reference resistor 100c may be calculated from Equation 1 as shown in Equation 5 below.

$${V}_{DIV 13} = \frac{{R}_{REF 1}}{( {R}_{P 1} ‖ {R}_{P 2} ) + {R}_{REF 1}} \times {V}_{D D} = \frac{50}{51 + 50} \times {V}_{D D} \approx 0.495 {V}_{D D} \qquad [ Equation 5 ]$$

The first comparator 300 sequentially compares voltages V_{DIV11}, V_{DIV12} and V_{DIV13} to 0.5×V_{DD} and outputs the comparison value V_{COMP1} for each of the voltages V_{DIV11}, V_{DIV12} and V_{DIV13}.

The comparison values outputted by the first comparator 300 are: V_{COMP11}=1 (∵0.515×V_{DD}>0.5×V_{DD}); V_{COMP12}=1 (∵0.505×V_{DD}>0.5×V_{DD}); and V_{COMP13}=0 (∵0.495×V_{DD}<0.5×V_{DD}) where the first comparison value V_{COMP11}, the second comparison value V_{COMP12} and the third comparison value V_{COMP13} represent the comparison results for the voltages V_{DIV11}, V_{DIV12} and V_{DIV13}, respectively.

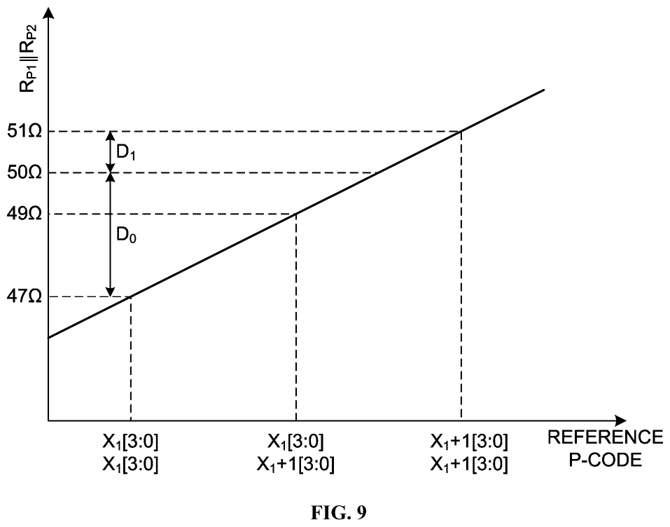

This change (1→1→0) of the first comparison value V_{COMP11}, the second comparison value V_{COMP12} and the third comparison value V_{COMP13} represents that R_{P1}∥R_{P2} increases as the applied reference P-code increases, as shown in FIG. 9, and in particular, when X₁+1 is applied to each of the first pull-up resistor 100a and the second pull-up resistor 100b, R_{P1}∥R_{P2} is then greater than 50Ω, which is the resistance R_{REF1} of the first reference resistor 100c.

That is, as shown in FIG. 9, when X₁+1 is applied to each of the first pull-up resistor 100a and the second pull-up resistor 100b, the difference D₁ between the resistance R_{P1}∥R_{P2} and the resistance R_{REF1} of the first reference resistor 100c is minimum (D₀<D₁).

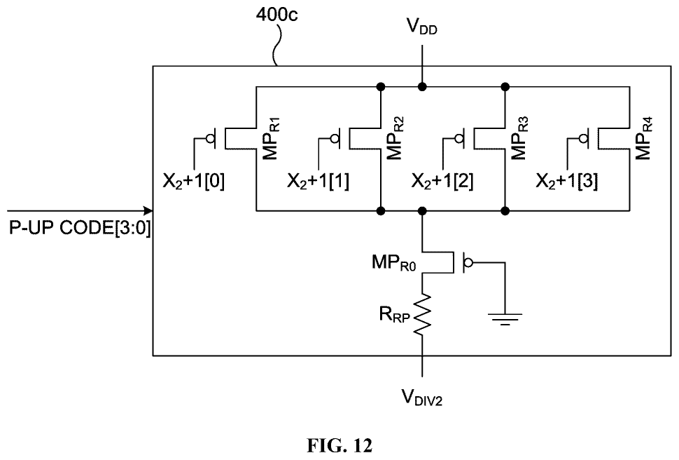

Therefore, the pull-up code selector 200 selects the second reference P-code [3:0] (=X₁+1) as the pull-up code [3:0], and applies the selected pull-up code [3:0] to the second reference resistor 400c shown in FIG. 12.

Next, to describe the pull-up code selection process of the pull-up code selector 200 for another reference P-code, it is assumed that K=4, the resistance R_{REF1} of the first reference resistor 100c is 50Ω, the resistance R_{P1} of the first pull-up resistor 100a and the resistance R_{P2} of the second pull-up resistor 100b are both 98Ω when the first reference P-code [3:0] (=X₂) is applied thereto, and the resistance R_{P1} of the first pull-up resistor 100a and the resistance R_{P2} of the second pull-up resistor 100b are both 106Ω when the second reference P-code [3:0] (=X₂+1) is applied.

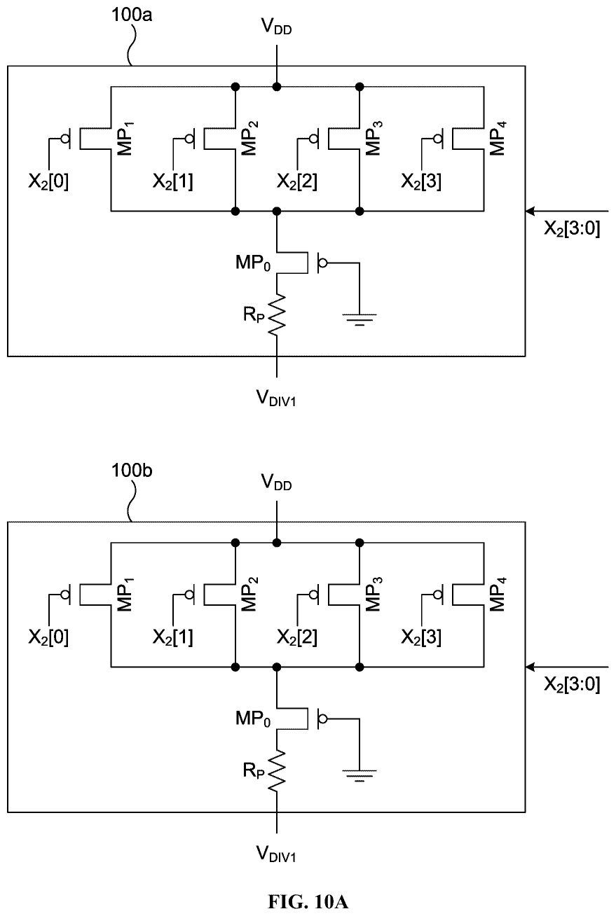

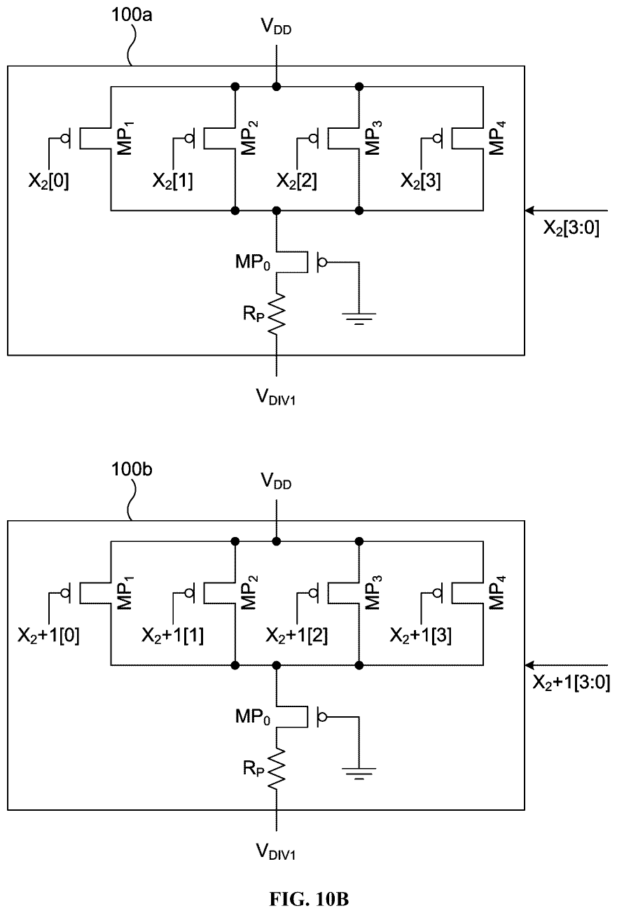

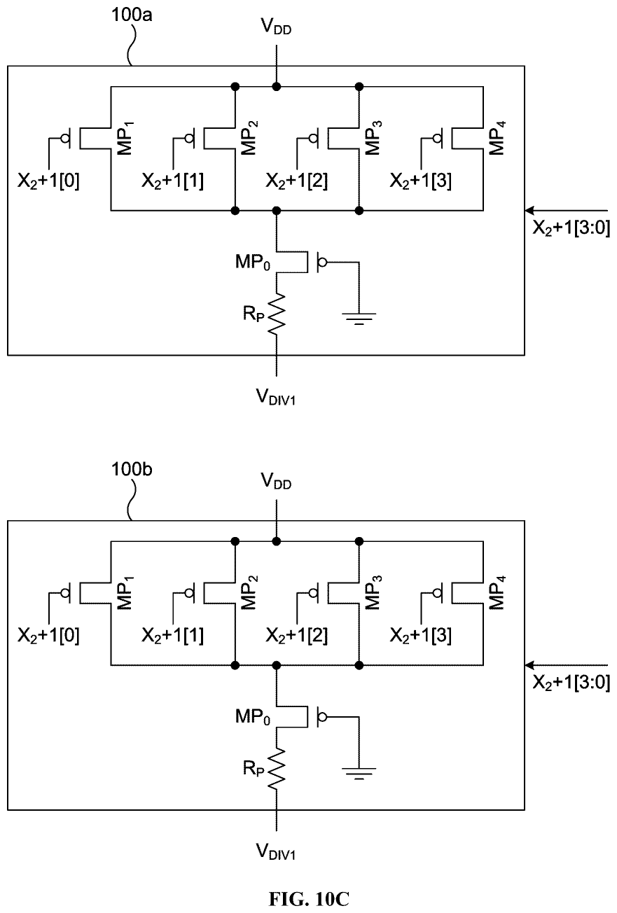

FIGS. 10A to 10C are circuit diagrams illustrating the first pull-up resistor 100a and the second pull-up resistor 100b when the first reference P-code [3:0] (=X₂) and the second reference P-code [3:0] (=X₂+1) are applied according to the present invention.

First, referring to FIG. 10A, the first reference P-code [3:0] (=X₂) is applied to each of the first pull-up resistor 100a and the second pull-up resistor 100b.

When X₂ is applied to each of the first pull-up resistor 100a and the second pull-up resistor 100b, the resistance R_{P1} of the first pull-up resistor 100a and the resistance R_{P2} of the second pull-up resistor 100b are both 98Ω. Thus, R_{P1}∥RP2=49Ω.

Here, the voltage V_{DIV11} across the first reference resistor 100c may be calculated from Equation 1 as shown in Equation 6 below.

$${V}_{DIV 11} = \frac{{R}_{REF 1}}{( {R}_{P 1} ‖ {R}_{P 2} ) + {R}_{REF 1}} \times {V}_{D D} = \frac{50}{49 + 50} \times {V}_{D D} \approx 0.505 {V}_{D D} \qquad [ Equation 6 ]$$

Next, referring to FIG. 10B, the first reference P-code [3:0] (=X₂) and the second reference P-code [3:0] (=X₂+1) are applied to the first pull-up resistor 100a and the second pull-up resistor 100b, respectively.

When X₂ and X₂+1 are applied to the first pull-up resistor 100a and the second pull-up resistor 100b, respectively, the resistance R_{P1} of the first pull-up resistor 100a and the resistance R_{P2} of the second pull-up resistor 100b are 98Ω and 106Ω, respectively. Thus, R_{P1}∥R_{P2}≈51Ω.

Here, the voltage V_{DIV12} across the first reference resistor 100c may be calculated from Equation 1 as shown in Equation 7 below.

$${V}_{DIV 12} = \frac{{R}_{REF 1}}{( {R}_{P 1} ‖ {R}_{P 2} ) + {R}_{REF 1}} \times {V}_{D D} = \frac{50}{51 + 50} \times {V}_{D D} \approx 0.495 {V}_{D D} \qquad [ Equation 7 ]$$

Next, referring to FIG. 10C, the second reference P-code [3:0] (=X₂+1) is applied to each of the first pull-up resistor 100a and the second pull-up resistor 100b.

When X₂+1 is applied to each of the first pull-up resistor 100a and the second pull-up resistor 100b, the resistance R_{P1} of the first pull-up resistor 100a and the resistance R_{P2} of the second pull-up resistor 100b are both 106Ω. Thus, R_{P1}∥R_{P2}=53Ω.

Here, the voltage V_{DIV13} across the first reference resistor 100c may be calculated from Equation 1 as shown in Equation 8 below.

$${V}_{DIV 13} = \frac{{R}_{REF 1}}{( {R}_{P 1} ‖ {R}_{P 2} ) + {R}_{REF 1}} \times {V}_{D D} = \frac{50}{53 + 50} \times {V}_{D D} \approx 0.485 {V}_{D D} \qquad [ Equation 8 ]$$

The first comparator 300 sequentially compares voltages V_{DIV11}, V_{DIV12} and V_{DIV13} to 0.5×V_{DD} and outputs the comparison value V_{COMP1} for each of the voltages V_{DIV11}, V_{DIV12} and V_{DIV13}.

The comparison values outputted by the first comparator 300 are: V_{COMP11}=1 (∵0.505×V_{DD}>0.5×V_{DD}); V_{COMP12}=0 (∵0.495×V_{DD}<0.5×V_{DD}); and V_{COMP13}=0 (∵0.485×V_{DD}<0.5×V_{DD}) where the first comparison value V_{COMP11}, the second comparison value V_{COMP12} and the third comparison value V_{COMP13} represent the comparison results for the voltages V_{DIV11}, V_{DIV12} and V_{DIV13}, respectively.

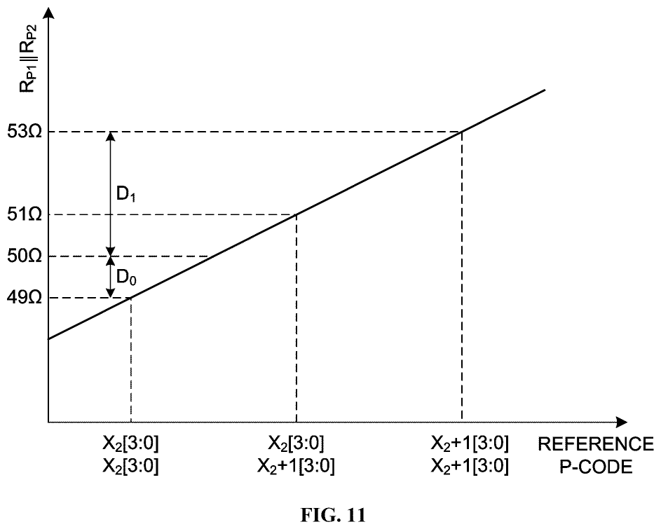

This change (1→0→0) of the first comparison value V_{COMP11}, the second comparison value V_{COMP12} and the third comparison value V_{COMP13} represents that R_{P1}∥R_{P2} increases as the applied reference P-code increases, as shown in FIG. 11, and in particular, when X₂ and X₂+1 are applied to the first pull-up resistor 100a and the second pull-up resistor 100b, respectively, R_{P1}∥R_{P2} is already greater than 50Ω, which is the resistance R_{REF1} of the first reference resistor 100c, and when X₂+1 is applied to each of the first pull-up resistor 100a and the second pull-up resistor 100b, R_{P1}∥R_{P2} is much greater than the resistance R_{REF1} of 50Ω of the first reference resistor 100c.

That is, as shown in FIG. 11, when X₂ is applied to each of the first pull-up resistor 100a and the second pull-up resistor 100b, the difference Do between the resistance R_{P1}∥R_{P2} and the resistance R_{REF1} of the first reference resistor 100c is minimum (D₀<D₁).

Therefore, the pull-up code selector 200 selects the first reference P-code [3:0] (=X₂) as the pull-up code [3:0], and applies the selected pull-up code [3:0] to the second reference resistor 400c shown in FIG. 12.

The pull-up code [3:0] applied to the second reference resistor 400c is a reference P-code which minimizes the difference between the resistance R_{REF2} of the second reference resistor 400c and the resistance R_{REF1} (=50Ω).

In the above-described pull-up code selection process, the first comparison value V_{COMP11}, the second comparison value V_{COMP12} and the third comparison value V_{COMP13} may have values different from those described above, which will be explained below.

In the above-described pull-up code selection process, the comparison results may be V_{COMP11}=1, V_{COMP12}=1, and V_{COMP13}=1. This means V_{DIV11}>0.5×V_{DD}, V_{DIV12}>0.5×V_{DD}, and V_{DIV13}>0.5×V_{DD}, respectively. That is, the voltage V_{DIV1} across the first reference resistor 100c in each comparison is greater than 0.5×V_{DD}. In such case, it is not possible to determine the pull-up code which minimizes the difference between the resistance R_{P1}∥R_{P2} and the resistance R_{REF1} of the first reference resistor 100c.

Therefore, the resistance R_{P1}∥R_{P2} should be increased or decreased by appropriately adjusting the first reference P-code [3:0] and the second reference P-code [3:0]. In order to make any one of the first comparison value V_{COMP11}, the second comparison value V_{COMP12}, and the third comparison value V_{COMP13} zero, the resistance R_{P1}∥R_{P2} in Equation 1 should be increased. As the first reference P-code [3:0] and the second reference P-code [3:0] increase, the resistance R_{P1}∥R_{P2} increases. Thus, the pull-up code selector 200 increases each of the first reference P-code [3:0] and the second reference P-code [3:0] by 1, and sequentially applies the increased first reference P-code [3:0] and the increased second reference P-code [3:0] to the first pull-up resistor 100a and the second pull-up resistor 100b, and perform the above-described process again with the newly obtained first comparison value V_{COMP11}, the newly obtained second comparison value V_{COMP12}, and the newly obtained third comparison value V_{COMP13}.

Similarly, when the comparison results are V_{COMP11}=0, V_{COMP12}=0, and V_{COMP13}=0, each of the first reference P-code [3:0] and the second reference P-code [3:0] are decreased by 1 to decrease the resistanceR_{P1}∥R_{P2}, and the above process is performed again with the first comparison value V_{COMP11}, the second comparison value V_{COMP12}, and the third comparison value V_{COMP13} newly obtained from the decreased first reference P-code [3:0] and the decreased second reference P-code [3:0].

The pull-up code selection process of the pull-up code selector 200 described above is summarized in Table 1 below.

TABLE 1

| V_{COMP11} | V_{COMP12} | V_{COMP13} | Pull-up code |
|---|---|---|---|
| 1 | 1 | 0 | Second reference P-code |
| 1 | 0 | 0 | First reference P-code |
| 1 | 1 | 1 | Increase first and second reference P-codes by 1 |
| 0 | 0 | 0 | Decrease first and second reference P-codes by 1 |
| 0 | 0 | 1 | Non-existent comparison values |
| 0 | 1 | 1 | |
| 1 | 0 | 1 | |
| 0 | 1 | 0 | |

Hereinafter, the pull-down code selection process of the pull-down code selector 500 is described when the pull-up code [3:0], which minimizes the difference between the resistance R_{REF2} of the second reference resistor 400c and the resistance R_{REF1} (=50Ω), is applied to the second reference resistor 400c.

Except that the second reference resistor 400c having the resistance determined by the pull-up code [3:0] is employed instead of the first reference resistor 100c having a constant resistance, the pull-down code selection process of the pull-down code selector 500 is substantially the same as that of the pull-up code selector 200.

First, in order to describe the pull-down code selection process of the pull-down code selector 500, it is assumed that K=4, the resistance R_{REF2} of the second reference resistor 400c is 50Ω when pull-up code [3:0] (=X₁+1) is applied, the resistance R_{N1} of the first pull-down resistor 400a and the resistance R_{N2} of the second pull-down resistor 400b are both 102Ω when the first reference N-code [3:0] (=Y₁) is applied thereto, and the resistance R_{N1} of the first pull-down resistor 400a and the resistance R_{N2} of the second pull-down resistor 400b are both 94Ω when the second reference N-code [3:0] (=Y₁+1) is applied.

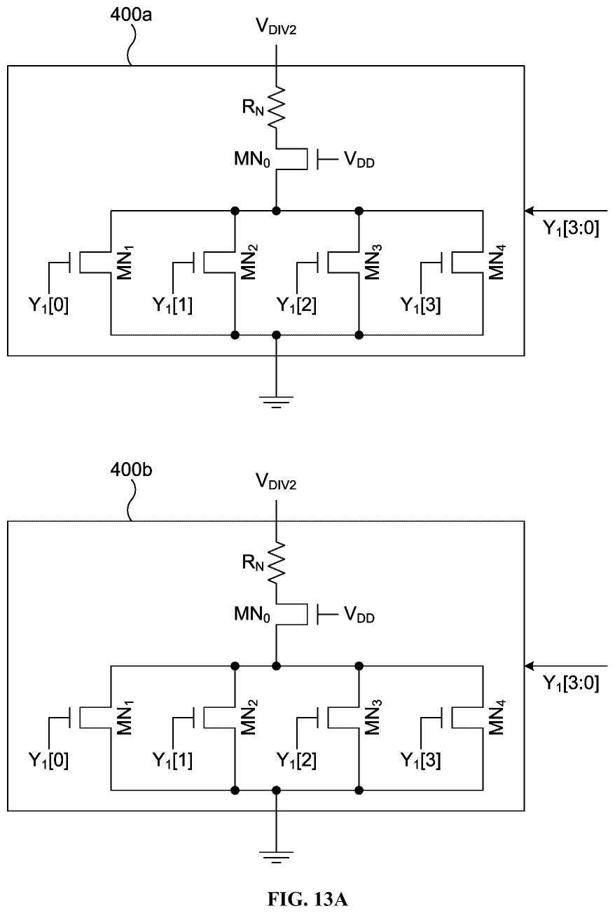

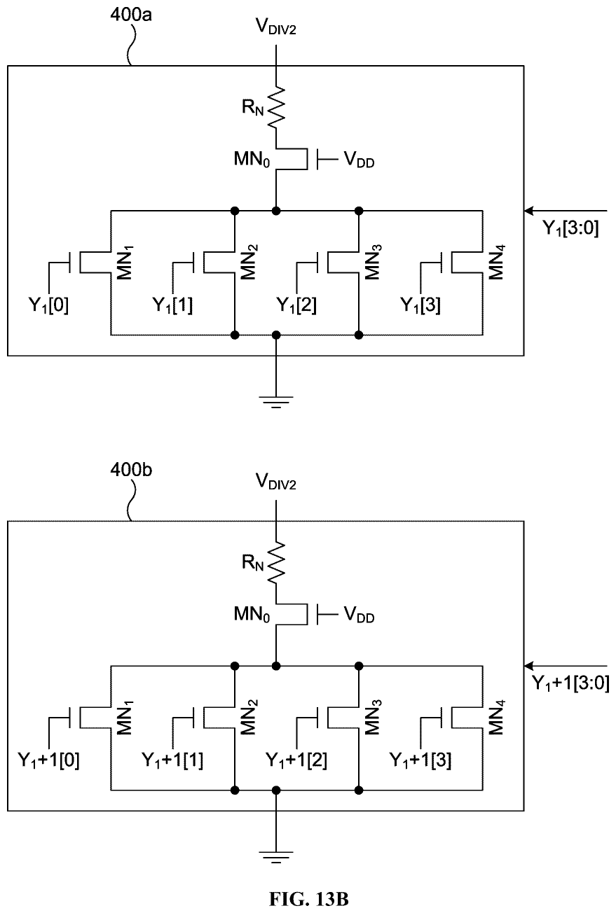

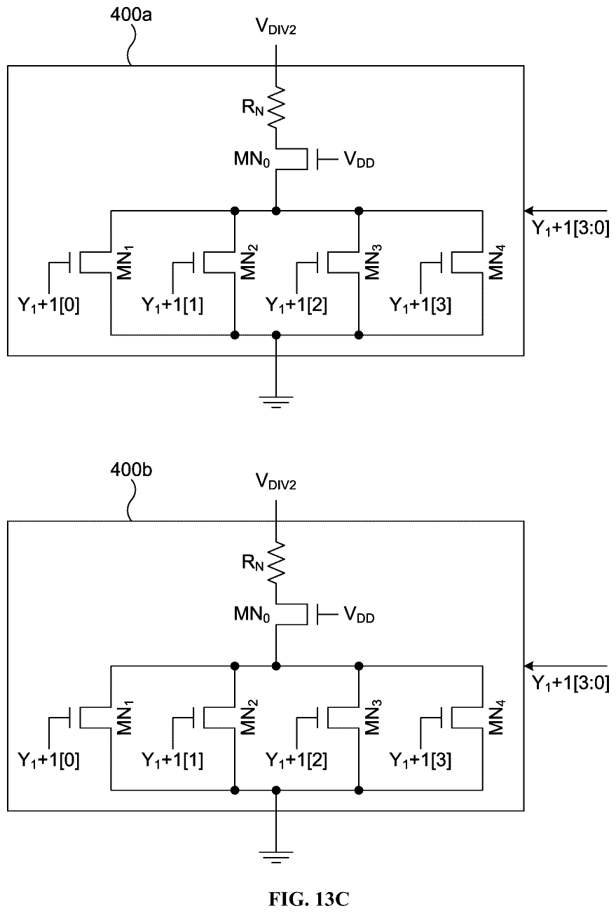

FIGS. 13A to 13C are circuit diagrams illustrating the first pull-down resistor 400a and the second pull-down resistor 400b, respectively, when the first reference N-code [3:0] (=Y₁) and the second reference N-code [3:0] (=Y₁+1) are applied according to the present invention.

First, referring to FIG. 13A, the first reference N-code [3:0] (=Y₁) is applied to each of the first pull-down resistor 400a and the second pull-down resistor 400b.

When Y₁ is applied to each of the first pull-down resistor 400a and the second pull-down resistor 400b, the resistance R_{N1} of the first pull-down resistor 400a and the resistance R_{N2} of the second pull-down resistor 400b are both 102Ω. Thus, R_{N1}∥R_{N2}=51Ω.

Here, the voltage V_{DIV21} across the first pull-down resistor 400a and the second pull-down resistor 400b connected in parallel may be calculated from Equation 2 as shown in Equation 9 below.

$${V}_{DIV 21} = \frac{( {R}_{N 1} ‖ {R}_{N 2} )}{( {R}_{N 1} ‖ {R}_{N 2} ) + {R}_{REF 2}} \times {V}_{D D} = \frac{51}{51 + 50} \times {V}_{D D} \approx 0.505 {V}_{D D} \qquad [ Equation 9 ]$$

Next, referring to FIG. 13B, the first reference N-code [3:0] (=Y₁) and the second reference N-code [3:0] (=Y₁+1) are applied to the first pull-down resistor 400a and the second pull-down resistor 400b, respectively.

When Y₁ and Y₁+1 are applied to the first pull-down resistor 400a and the second pull-down resistor 400b, respectively, the resistance R_{N1} of the first pull-down resistor 400a and the resistance R_{N2} of the second pull-down resistor 400b are 102Ω and 94Ω, respectively. Thus, R_{N1}∥R_{N2}˜49Ω.

Here, the voltage V_{DIV22} across the first pull-down resistor 400a and the second pull-down resistor 400b connected in parallel may be calculated from Equation 2 as shown in Equation 10 below.

$${V}_{DIV 22} = \frac{( {R}_{N 1} ‖ {R}_{N 2} )}{( {R}_{N 1} ‖ {R}_{N 2} ) + {R}_{REF 2}} \times {V}_{D D} = \frac{49}{49 + 50} \times {V}_{D D} \approx 0.495 {V}_{D D} \qquad [ Equation 10 ]$$

Next, referring to FIG. 13C, the second reference N-code [3:0] (=Y₁+1) is applied to each of the first pull-down resistor 400a and the second pull-down resistor 400b.

When Y₁+1 is applied to each of the first pull-down resistor 400a and the second pull-down resistor 400b, the resistance R_{N1} of the first pull-down resistor 400a and the resistance R_{N2} of the second pull-down resistor 400b are both 94Ω. Thus, R_{N1}∥R_{N2}=47Ω.

Here, the voltage V_{DIV23} across the first pull-down resistor 400a and the second pull-down resistor 400b connected in parallel may be calculated from Equation 2 as shown in Equation 11 below.

$${V}_{DIV 23} = \frac{( {R}_{N 1} ‖ {R}_{N 2} )}{( {R}_{N 1} ‖ {R}_{N 2} ) + {R}_{REF 2}} \times {V}_{D D} = \frac{47}{47 + 50} \times {V}_{D D} \approx 0.485 {V}_{D D} \qquad [ Equation 11 ]$$

The second comparator 600 sequentially compares voltages V_{DIV21}, V_{DIV22} and V_{DIV23} to 0.5×V_{DD} and outputs the comparison value V_{COMP2} for each of the voltages V_{DIV21}, V_{DIV22} and V_{DIV23}.

The comparison values outputted by the second comparator 600 are: V_{COMP21}=1 (∵0.505×V_{DD}>0.5×V_{DD}); V_{COMP22}=0 (∵0.495×V_{DD}<0.5×V_{DD}); and V_{COMP23}=0 (∵0.485×V_{DD}<0.5×V_{DD}) where first comparison value V_{COMP21}, second comparison value V_{COMP22} and third comparison value V_{COMP23} represent the comparison results for the voltages V_{DIV21}, V_{DIV22} and V_{DIV23}, respectively.

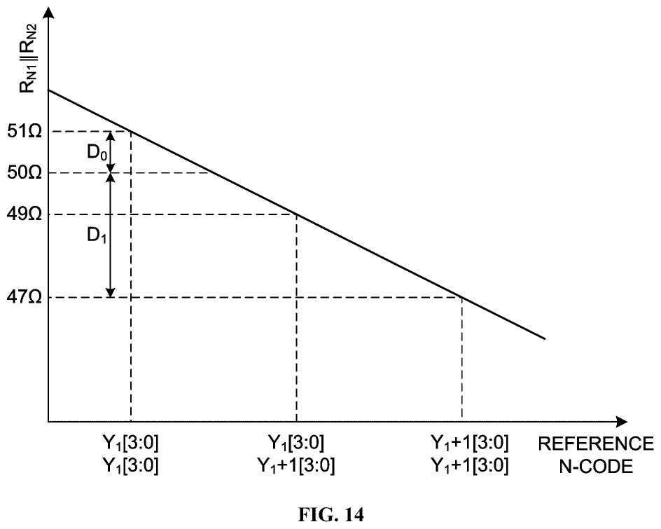

This change (1→0→0) of the first comparison value V_{COMP21}, the second comparison value V_{COMP22} and the third comparison value V_{COMP23} represents that R_{N1}∥R_{N2} decreases as the applied reference N-code increases, as shown in FIG. 14, and in particular, when Y₁ and Y₁+1 are applied to each of the first pull-down resistor 400a and the second pull-down resistor 400b, respectively, R_{N1}∥R_{N2} is smaller than 50Ω, which is the resistance R_{REF2} of the second reference resistor 400c, and when Y₁+1 is applied to each of the first pull-down resistor 400a and the second pull-down resistor 400b, R_{N1}∥R_{N2} is much smaller than 50Ω, which is the resistance R_{REF2} of the second reference resistor 400c.

That is, as shown in FIG. 14, when Y₁ is applied to each of the first pull-down resistor 400a and the second pull-down resistor 400b, the difference Do between the resistance R_{N1}∥R_{N2} and the resistance R_{REF2} of the second reference resistor 400c is minimum (D₀<D₁). Therefore, the pull-down code selector 500 selects the first reference N-code [3:0] (=Y₁) as the pull-down code [3:0].

Next, to describe the pull-down code selection process of the pull-down code selector 500 for another reference N-code, it is assumed that K=4, the resistance R_{REF2} of the second reference resistor 400c is 50Ω, the resistance R_{N1} of the first pull-down resistor 400a and the resistance R_{N2} of the second pull-down resistor 400b are both 106Ω when the first reference N-code [3:0] (=Y₂) is applied thereto, and the resistance R_{N1} of the first pull-down resistor 400a and the resistance R_{N2} of the second pull-down resistor 400b are both 98Ω when the second reference N-code [3:0] (=Y₂+1) is applied.

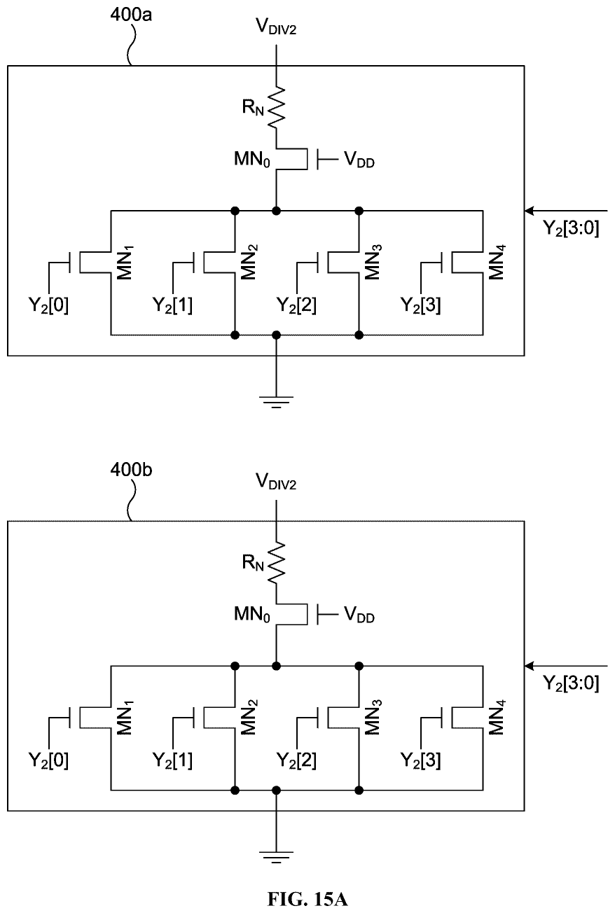

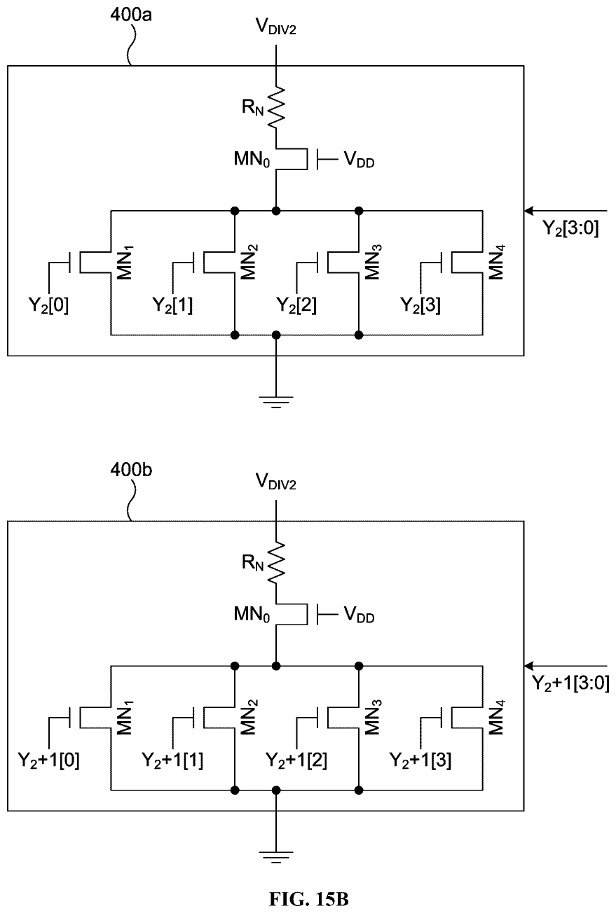

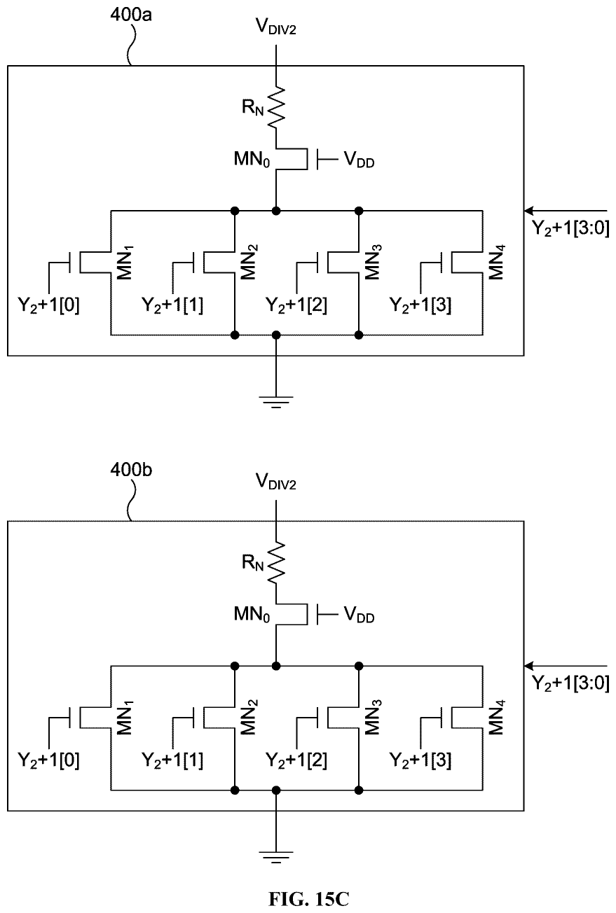

FIGS. 15A to 15C are circuit diagrams illustrating the first pull-down resistor 400a and the second pull-down resistor 400b when the first reference N-code [3:0] (=Y₂) and the second reference N-code [3:0] (=Y₂+1) are applied according to the present invention.

First, referring to FIG. 15A, the first reference N-code [3:0] (=Y₂) is applied to each of the first pull-down resistor 400a and the second pull-down resistor 400b.

When Y₂ is applied to each of the first pull-down resistor 400a and the second pull-down resistor 400b, the resistance R_{N1} of the first pull-down resistor 400a and the resistance R_{N2} of the second pull-down resistor 400b are both 106Ω. Thus, R_{N1}∥R_{N2}=53Ω.

Here, the voltage V_{DIV21} across the first pull-down resistor 400a and the second pull-down resistor 400b connected in parallel may be calculated from Equation 2 as shown in Equation 12 below.

$${V}_{DIV 21} = \frac{( {R}_{N 1} ‖ {R}_{N 2} )}{( {R}_{N 1} ‖ {R}_{N 2} ) + {R}_{REF 2}} \times {V}_{D D} = \frac{53}{53 + 50} \times {V}_{D D} \approx 0.515 {V}_{D D} \qquad [ Equation 12 ]$$

Next, referring to FIG. 15B, the first reference N-code [3:0] (=Y₂) and the second reference N-code [3:0] (=Y₂+1) are applied to the first pull-down resistor 400a and the second pull-down resistor 400b, respectively.

When Y₂ and Y₂+1 are applied to the first pull-down resistor 400a and the second pull-down resistor 400b, respectively, the resistance R_{N1} of the first pull-down resistor 400a and the resistance R_{N2} of the second pull-down resistor 400b are 106Ω and 98Ω, respectively. Thus, R_{N1}∥R_{N2}≈51Ω.

Here, the voltage V_{DIV22} across the first pull-down resistor 400a and the second pull-down resistor 400b connected in parallel may be calculated from Equation 2 as shown in Equation 13 below.

$${V}_{DIV 22} = \frac{( {R}_{N 1} ‖ {R}_{N 2} )}{( {R}_{N 1} ‖ {R}_{N 2} ) + {R}_{REF 2}} \times {V}_{D D} = \frac{51}{51 + 50} \times {V}_{D D} \approx 0.505 {V}_{D D} \qquad [ Equation 13 ]$$

Next, referring to FIG. 15C, the second reference N-code [3:0] (=Y₂+1) is applied to each of the first pull-down resistor 400a and the second pull-down resistor 400b.

When Y₂+1 is applied to each of the first pull-down resistor 400a and the second pull-down resistor 400b, the resistance R_{N1} of the first pull-down resistor 400a and the resistance R_{N2} of the second pull-down resistor 400b are both 98Ω. Thus, R_{N1}∥R_{N2}=49Ω.

Here, the voltage V_{DIV23} across the first pull-down resistor 400a and the second pull-down resistor 400b connected in parallel may be calculated from Equation 2 as shown in Equation 14 below.

$${V}_{DIV 23} = \frac{( {R}_{N 1} ‖ {R}_{N 2} )}{( {R}_{N 1} ‖ {R}_{N 2} ) + {R}_{REF 2}} \times {V}_{D D} = \frac{49}{49 + 50} \times {V}_{D D} \approx 0.495 {V}_{D D} \qquad [ Equation 14 ]$$

The second comparator 600 sequentially compares voltages V_{DIV21}, V_{DIV22} and V_{DIV23} to 0.5×V_{DD} and outputs the comparison value V_{COMP2} for each of the voltages V_{DIV21}, V_{DIV22} and V_{DIV23}.

The comparison values outputted by the second comparator 600 are: V_{COMP21}=1 (∵0.515×V_{DD}>0.5×V_{DD}); V_{COMP22}=1 (0.505×V_{DD}>0.5×V_{DD}); and V_{COMP23}=0 (∵0.495×V_{DD}<0.5×V_{DD}) where first comparison value V_{COMP21}, second comparison value V_{COMP22} and third comparison value V_{COMP23} represent the comparison values for the voltages V_{DIV21}, V_{DIV22} and V_{DIV23}, respectively.

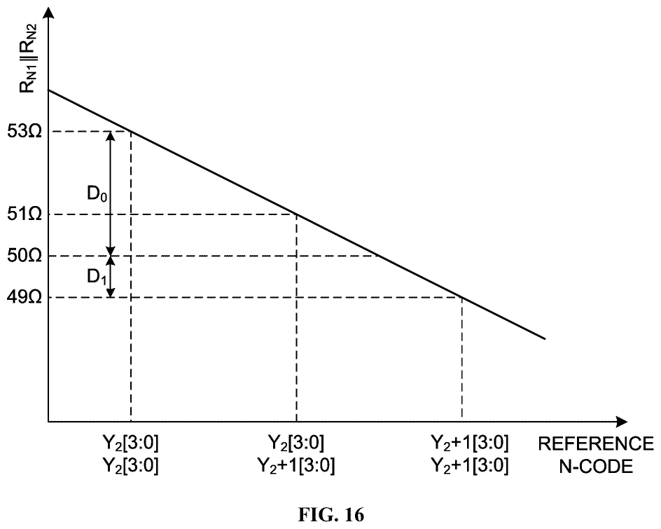

This change (1→1→0) of the first comparison value V_{COMP21}, the second comparison value V_{COMP22} and third comparison value V_{COMP23} represents that R_{N1}∥R_{N2} decreases as the applied reference N-code increases, as shown in FIG. 16, and in particular, when Y₂+1 is applied to each of the first pull-down resistor 400a and the second pull-down resistor 400b, R_{N1}∥R_{N2} is then smaller than 50Ω, which is the resistance R_{REF2} of the second reference resistor 400c.

That is, as shown in FIG. 16, when Y₂+1 is applied to each of the first pull-down resistor 400a and the second pull-down resistor 400b, the difference D₁ between the resistance R_{N1}∥R_{N2} and the resistance R_{REF2} of the second reference resistor 400c is minimum (D₀>D₁). Therefore, the pull-down code selector 500 selects the first reference N-code [3:0] (=Y₂) as the pull-down code [3:0].

In the above-described pull-down code selection process, the first comparison value V_{COMP21}, the second comparison value V_{COMP22} and the third comparison value V_{COMP23} may have values different from those described above, which will be explained below.

In the above-described pull-down code selection process, the comparison results may be V_{COMP21}=1, V_{COMP22}=1, and V_{COMP23}=1. This means V_{DIV21}>0.5×V_{DD}, V_{DIV22}>0.5×V_{DD}, and V_{DIV23}>0.5×V_{DD}, respectively. That is, the voltage V_{DIV2} across the first pull-down resistor 400a and the second pull-down resistor 400b connected in parallel in each comparison is greater than 0.5×V_{DD}. In such case, it is not possible to determine the pull-down code which minimizes the difference between the resistance R_{N1}∥R_{N2} and the resistance R_{REF2} of the second reference resistor 400c.

Therefore, the resistance R_{N1}∥R_{N2} should be increased or decreased by appropriately adjusting the first reference N-code [3:0] and the second reference N-code [3:0]. In order to make any one of the first comparison value V_{COMP21}, the second comparison value V_{COMP22}, and the third comparison value V_{COMP23} zero, the resistance R_{N1}∥R_{N2} in Equation 2 should be decreased. As the first reference N-code [3:0] and the second reference N-code [3:0] increase, the resistance R_{N1}∥R_{N2} decreases. Thus, the pull-down code selector 500 increases each of the first reference N-code [3:0] and the second reference N-code [3:0] by 1, and sequentially applies the increased first reference N-code [3:0] and the increased second reference N-code [3:0] to the first pull-down resistor 400a and the second pull-down resistor 400b, and perform the above-described process again with the newly obtained first comparison value V_{COMP21}, the newly obtained second comparison value V_{COMP22}, and the newly obtained third comparison value V_{COMP23}.

Similarly, when the comparison results are V_{COMP21}=0, V_{COMP22}=0, and V_{COMP2}=0, each of the first reference N-code [3:0] and the second reference N-code [3:0] are decreased by 1 to increase the resistance R_{N1}∥R_{N2}, and the above process is performed again with the first comparison value V_{COMP21}, the second comparison value V_{COMP22}, and the third comparison value V_{COMP23} newly obtained from the decreased first reference N-code [3:0] and the decreased second reference N-code [3:0].

The pull-down code selection process of the pull-down code selector 500 described above is summarized in Table 2 below.

TABLE 2

| V_{COMP21} | V_{COMP22} | V_{COMP23} | Pull-down code |
|---|---|---|---|
| 1 | 1 | 0 | Second reference N-code |
| 1 | 0 | 0 | First reference N-code |
| 1 | 1 | 1 | Increase first and second reference N-codes by 1 |
| 0 | 0 | 0 | Decrease first and second reference N-codes by 1 |
| 0 | 0 | 1 | Non-existent comparison values |
| 0 | 1 | 1 | |
| 1 | 0 | 1 | |
| 0 | 1 | 0 | |

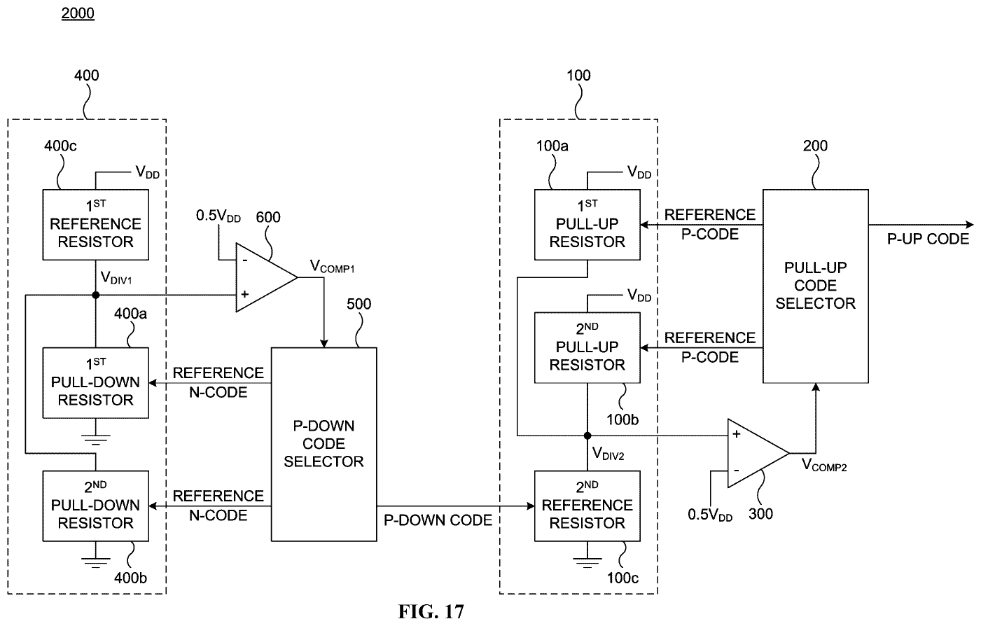

FIG. 17 is a circuit diagram illustrating a circuit capable of automatically adjusting impedance thereof according to a second embodiment of the present invention.

Referring to FIG. 17, a circuit 2000 capable of automatically adjusting impedance thereof according to the second embodiment of the present invention includes: a first voltage divider 400; a pull-down code selector 500; a first comparator 600; a second voltage divider 100; a pull-up code selector 200; and a second comparator 300.

The first voltage divider 400, the pull-down code selector 500, the first comparator 600, the second voltage divider 100, the pull-up code selector 200 and the second comparator 300 constituting the circuit 2000 capable of automatically adjusting impedance thereof according to the second embodiment of the present invention are identical in operation and function to the second voltage divider 400, the pull-down code selector 500, the second comparator 600, the first voltage divider 100, the pull-up code selector 200 and the first comparator 300 constituting the circuit 1000 capable of automatically adjusting impedance thereof according to the first embodiment, respectively.

However, the circuit 2000 capable of automatically adjusting impedance thereof according to the second embodiment differs from the circuit 1000 capable of automatically adjusting impedance thereof according to the first embodiment in that the pull-down code is determined first and then the pull-up code is determined, and the resistance of the second reference resistor 400c is constant, while the resistance of the second reference resistor 100c is determined by the pull-down code determined by the pull-down code selector 500.

That is, the first voltage divider 400 according to the second embodiment of the present invention includes: a first pull-down resistor 400a and a second pull-down resistor 400b connected in parallel and having resistances, respectively, varying according to a reference N-code [K-1:0] applied thereto; and a first reference resistor 400c having a constant resistance and connected in series with the first pull-down resistor 400a and the second pull-down resistor 400b connected in parallel, the pull-down code selector 500 according to the second embodiment of the present invention sequentially applies: a first reference N-code [K-1:0] and the first reference N-code [K-1:0] to the first pull-down resistor 400a and the second pull-down resistor 400b, respectively; the first reference N-code [K-1:0] and a second reference N-code [K-1:0] to the first pull-down resistor 400a and the second pull-down resistor 400b, respectively; and the second reference N-code [K-1:0] and the second reference N-code [K-1:0] to the first pull-down resistor 400a and the second pull-down resistor 400b, respectively, the first comparator 600 according to the second embodiment of the present invention provides a comparison value V_{COMP1} to the pull-down code selector 500 wherein the comparison value V_{COMP1} is obtained by comparing 0.5×V_{DD} to a voltage V_{DIV1} across the first pull-down resistor 400a and the second pull-down resistor 400b connected in parallel when a voltage V_{DD} is applied to the first voltage divider 400, the second voltage divider 100 according to the second embodiment of the present invention includes: a second reference resistor 100c having a resistance varying according to a pull-down code applied by the pull-down code selector 500; and a first pull-up resistor 100a and a second pull-up resistor 100b connected in parallel and having resistances, respectively, varying according to a reference P-code [K-1:0] applied thereto wherein the first pull-up resistor 100a and the second pull-up resistor 100b are connected in series with the second reference resistor 100c, the pull-up code selector 200 according to the second embodiment of the present invention sequentially applies: a first reference P-code [K-1:0] and the first reference P-code [K-1:0] to the first pull-up resistor 100a and the second pull-up resistor 100b, respectively; the first reference P-code [K-1:0] and a second reference P-code [K-1:0] to the first pull-up resistor 100a and the second pull-up resistor 100b, respectively; and the second reference P-code [K-1:0] and the second reference P-code [K-1:0] to the first pull-up resistor 100a and the second pull-up resistor 100b, respectively; and the second comparator 300 according to the second embodiment of the present invention provides a comparison value V_{COMP2} to the pull-up code selector 200 wherein the comparison value V_{COMP2} is obtained by comparing 0.5×V_{DD} to a voltage V_{DIV2} across the second reference resistor 100c when the voltage V_{DD} is applied to the second voltage divider 100.

In addition, the first comparator 600 according to the second embodiment of the present invention performs a comparison each time the reference N-code [K-1:0] is applied and provides three comparison values V_{COMP1} to the pull-down code selector 500, the pull-down code selector 500 selects one of the first reference N-code [K-1:0] and the second reference N-code [K-1:0] as a pull-down code based on the three comparison values V_{COMP1}, the pull-down code minimizing a difference between: a resistance of the first reference resistor 400c; and a resistance of the first pull-down resistor 400a and the second pull-down resistor 400b connected in parallel, the second comparator 300 performs a comparison each time the reference P-code [K-1:0] is applied and provides three comparison values V_{COMP2} to the pull-up code selector 200, and the pull-up code selector 200 selects one of the first reference P-code [K-1:0] and the second reference P-code [K-1:0] as a pull-up code based on the three comparison values V_{COMP2}, the pull-up code minimizing the difference between: a resistance of the second reference resistor 100c; and a resistance of the first pull-up resistor 100a and the second pull-up resistor 100b connected in parallel (where “second reference N-code [K-1:0]” is equal to “first reference N-code [K-1:0]+1”, and “second reference P-code [K-1:0]” is equal to “first reference P-code [K-1:0]+1”).

The circuit capable of automatically adjusting impedance thereof according to the present invention has the following advantages.
(1) The circuit capable of automatically adjusting impedance thereof according to the present invention is advantageous in that large PVT changes may be dealt with due to the wide adjustment range of impedance.
(2) The circuit capable of automatically adjusting impedance thereof according to the present invention is advantageous in that internal resistance may be adjusted as closely as possible to the resistance of an external reference resistor with high accuracy.

What is claimed is:

1. A circuit capable of automatically adjusting impedance thereof, the circuit comprising:
a first voltage divider comprising: a first pull-up resistor and a second pull-up resistor connected in parallel and having resistances, respectively, varying according to a reference P-code applied thereto; and a first reference resistor having a constant resistance and connected in series with the first pull-up resistor and the second pull-up resistor connected in parallel,
a pull-up code selector sequentially applying: a first reference P-code and the first reference P-code; the first reference P-code and a second reference P-code; and the second reference P-code and the second reference P-code to the first pull-up resistor and the second pull-up resistor, respectively;
a first comparator providing a comparison value V_{COMP1} to the pull-up code selector wherein the comparison value V_{COMP1} is obtained by comparing 0.5×V_{DD} to a voltage V_{DIV1} across the first reference resistor when a voltage V_{DD} is applied to the first voltage divider;
a second voltage divider comprising: a second reference resistor having a resistance varying according to a pull-up code applied by the pull-up code selector; and a first pull-down resistor and a second pull-down resistor connected in parallel and having resistances, respectively, varying according to a reference N-code applied thereto wherein the first pull-down resistor and the second pull-down resistor are connected in series with the second reference resistor;
a pull-down code selector sequentially applying: a first reference N-code and the first reference N-code; the first reference N-code and a second reference N-code; and the second reference N-code and the second reference N-code to the first pull-down resistor and the second pull-down resistor, respectively; and
a second comparator providing a comparison value V_{COMP2} to the pull-down code selector wherein the comparison value V_{COMP2} is obtained by comparing 0.5×V_{DD} to a voltage V_{DIV2} across the first pull-down resistor and the second pull-down resistor when the voltage V_{DD} is applied to the second voltage divider,
wherein the first comparator performs a comparison each time the reference P-code is applied and provides three comparison values V_{COMP1} to the pull-up code selector,
the pull-up code selector selects one of the first reference P-code and the second reference P-code as a pull-up code based on the three comparison values V_{COMP1}, the pull-up code minimizing a difference between: a resistance of the first reference resistor; and a resistance of the first pull-up resistor and the second pull-up resistor connected in parallel,
the second comparator performs a comparison each time the reference N-code is applied and provides three comparison values V_{COMP2} to the pull-down code selector, and
the pull-down code selector selects one of the first reference N-code and the second reference N-code as a pull-down code based on the three comparison values V_{COMP2}, the pull-down code minimizing the difference between: a resistance of the second reference resistor; and a resistance of the first pull-down resistor and the second pull-down resistor connected in parallel (where “second reference P-code” is equal to “first reference P-code+1”, and “second reference N-code” is equal to “first reference N-code+1”).

2. The circuit of claim 1, wherein the reference P-code comprises binary data of K bits, and
each of the first pull-up resistor and the second pull-up resistor comprises K counts of PMOS transistors provided with gates having the binary data of K bits applied thereto, respectively (where K is a natural number).

3. The circuit of claim 1, wherein the three comparison values V_{COMP1} comprise a first comparison value, a second comparison value and a third comparison value, and
the pull-up code selector selects the first reference P-code as the pull-up code when the first comparison value=1, the second comparison value=0 and the third comparison value=0 are satisfied, and selects the second reference P-code as the pull-up code when the first comparison value=1, the second comparison value=1 and the third comparison value=0 are satisfied.

4. The circuit of claim 3, wherein the pull-up code selector:
(i) increases each of the first reference P-code and the second reference P-code by 1 and then sequentially applies increased first reference P-code and increased second reference P-code to the first pull-up resistor and the second pull-up resistor when the first comparison value=1, the second comparison value=1, and the third comparison value=1 are satisfied; and
(ii) selects one of the increased first reference P-code and the increased second reference P-code as the pull-up code based on comparison values of the first comparator obtained from the increased first reference P-code and the increased second reference P-code, the pull-up code minimizing the difference between: the resistance of the first reference resistor; and the resistance of the first pull-up resistor and the second pull-up resistor connected in parallel.

5. The circuit of claim 4, wherein the pull-up code selector:
(i) decreases each of the first reference P-code and the second reference P-code by 1 and then sequentially applies decreased first reference P-code and decreased second reference P-code to the first pull-up resistor and the second pull-up resistor when the first comparison value=0, the second comparison value=0, and the third comparison value=0 are satisfied; and
(ii) selects one of the decreased first reference P-code and the decreased second reference P-code as the pull-up code based on comparison values of the first comparator obtained from the decreased first reference P-code and the decreased second reference P-code, the pull-up code minimizing the difference between: the resistance of the first reference resistor; and the resistance of the first pull-up resistor and the second pull-up resistor connected in parallel.

6. The circuit of claim 1, wherein the reference N-code comprises binary data of K bits, and
each of the first pull-down resistor and the second pull-down resistor comprises K counts of NMOS transistors provided with gates having the binary data of K bits applied thereto, respectively (where K is a natural number).

7. The circuit of claim 1, wherein the three comparison values V_{COMP2} comprise a first comparison value, a second comparison value and a third comparison value, and
the pull-down code selector selects the first reference N-code as the pull-down code when the first comparison value=1, the second comparison value=0 and the third comparison value=0 are satisfied, and selects the second reference N-code as the pull-down code when the first comparison value=1, the second comparison value=1 and the third comparison value=0 are satisfied.

8. The circuit of claim 7, wherein the pull-down code selector:
(i) increases each of the first reference N-code and the second reference N-code by 1 and then sequentially applies increased first reference N-code and increased second reference N-code to the first pull-down resistor and the second pull-down resistor when the first comparison value=1, the second comparison value=1, and the third comparison value=1 are satisfied; and
(ii) selects one of the increased first reference N-code and the increased second reference N-code as the pull-down code based on comparison values of the second comparator obtained from the increased first reference N-code and the increased second reference N-code, the pull-down code minimizing the difference between: the resistance of the second reference resistor; and the resistance of the first pull-down resistor and the second pull-down resistor connected in parallel.

9. The circuit of claim 8, wherein the pull-down code selector:
(i) decreases each of the first reference N-code and the second reference N-code by 1 and then sequentially applies decreased first reference N-code and decreased second reference N-code to the first pull-down resistor and the second pull-down resistor when the first comparison value=0, the second comparison value=0, and the third comparison value=0 are satisfied; and
(ii) selects one of the decreased first reference N-code and the decreased second reference N-code as the pull-down code based on comparison values of the second comparator obtained from the decreased first reference N-code and the decreased second reference N-code, the pull-down code minimizing the difference between: the resistance of the second reference resistor; and the resistance of the first pull-down resistor and the second pull-down resistor connected in parallel.

10. A circuit capable of automatically adjusting impedance thereof, the circuit comprising:
a first voltage divider comprising: a first pull-down resistor and a second pull-down resistor connected in parallel and having resistances, respectively, varying according to a reference N-code applied thereto; and a first reference resistor having a constant resistance and connected in series with the first pull-down resistor and the second pull-down resistor connected in parallel,
a pull-down code selector sequentially applying: a first reference N-code and the first reference N-code; the first reference N-code and a second reference N-code; and the second reference N-code and the second reference N-code to the first pull-down resistor and the second pull-down resistor, respectively;
a first comparator providing a comparison value V_{COMP1} to the pull-down code selector wherein the comparison value V_{COMP1} is obtained by comparing 0.5×V_{DD} to a voltage V_{DIV1} across the first pull-down resistor and the second pull-down resistor connected in parallel when a voltage V_{DD} is applied to the first voltage divider;
a second voltage divider comprising: a second reference resistor having a resistance varying according to a pull-down code applied by the pull-down code selector; and a first pull-up resistor and a second pull-up resistor connected in parallel and having resistances, respectively, varying according to a reference P-code applied thereto wherein the first pull-up resistor and the second pull-up resistor are connected in series with the second reference resistor;
a pull-up code selector sequentially applying: a first reference P-code and the first reference P-code; the first reference P-code and a second reference P-code; and the second reference P-code and the second reference P-code to the first pull-up resistor and the second pull-up resistor, respectively; and
a second comparator providing a comparison value V_{COMP2} to the pull-up code selector wherein the comparison value V_{COMP2} is obtained by comparing 0.5×V_{DD} to a voltage V_{DIV2} across the second reference resistor when the voltage V_{DD} is applied to the second voltage divider,
wherein the first comparator performs a comparison each time the reference N-code is applied and provides three comparison values V_{COMP1} to the pull-down code selector,
the pull-down code selector selects one of the first reference N-code and the second reference N-code as a pull-down code based on the three comparison values V_{COMP1}, the pull-down code minimizing a difference between: a resistance of the first reference resistor; and a resistance of the first pull-down resistor and the second pull-down resistor connected in parallel,
the second comparator performs a comparison each time the reference P-code is applied and provides three comparison values V_{COMP2} to the pull-up code selector, and
the pull-up code selector selects one of the first reference P-code and the second reference P-code as a pull-up code based on the three comparison values V_{COMP2}, the pull-up code minimizing the difference between: a resistance of the second reference resistor; and a resistance of the first pull-up resistor and the second pull-up resistor connected in parallel (where “second reference N-code” is equal to “first reference N-code+1”, and “second reference P-code” is equal to “first reference P-code+1”).
